(19) United States
(12) Patent Application Publication
(10) Pub. No.: US 2024/0133802 A1
(43) Pub. Date: Apr. 25, 2024

(54) METHOD FOR ENCLOSING REFERENCE GASES IN MEMS CELLS

(71) Applicant: HAHN-SCHICKARD-GESELLSCHAFT FÜR ANGEWANDTE FORSCHUNG E. V., Villingen-Schwenningen (DE)

(72) Inventors: Achim BITTNER, Heilbronn (DE); Alfons DEHÉ, Reutlingen (DE); Ananya SRIVASTAVA, Villingen-Schwenningen (DE)

(21) Appl. No.: 18/548,517

(22) PCT Filed: Mar. 4, 2022
(86) PCT No.: PCT/EP2022/055582

§ 371 Date: Aug. 30, 2023

(30) Foreign Application Priority Data
Mar. 4, 2021 (EP) 21160684.3

(51) Int. Cl. G01N 21/17; B81C 1/00; G01N 21/3504; G01N 29/24

(52) U.S. Cl. CPC G01N 21/1702; B81C 1/00047; G01N 21/3504; G01N 29/2425; B81C 2201/019; G01N 2021/1704

(57) ABSTRACT

In a first aspect, the invention relates to a method for producing a gas-filled reference chamber which is hermetically sealed. Thereby, the gas with which the reference chamber is filled is introduced via an opening in a separate coating chamber only after bonding of the wafers forming the reference chamber. The reference chamber preferably contains MEMS devices.

In another aspect, the invention relates to a photoacoustic gas sensor comprising such a reference chamber within which a MEMS sensor is present.

In a first aspect, the invention relates to a method for producing a gas-filled reference chamber which is hermetically sealed. Thereby, the gas with which the reference chamber is filled is introduced via an opening in a separate coating chamber, after the wafers forming the reference chamber have bonded. MEMS devices are preferably installed in the reference chamber.

In another aspect, the invention relates to a photoacoustic gas sensor comprising such a reference chamber within which a MEMS sensor is present.

### BACKGROUND AND PRIOR ART

Photoacoustic spectroscopy (PAS) is a physical testing procedure based on the photoacoustic effect and has wide-ranging applications.

One application of PAS is the detection of very fine concentrations of gases. Here, intensity-modulated infrared radiation is used with frequencies in the absorption spectrum of the molecule to be detected in the gas. If this molecule is present in the beam path, modulated absorption takes place, leading to heating and cooling processes whose time scales reflect the modulation frequency of the radiation. The heating and cooling processes lead to expansions and contractions of the gas, causing sound waves at the modulation frequency. These can then be measured by sound detectors, such as microphones or flow sensors.

One example is the detection of CO₂, which plays a role in research and air conditioning technology. However, applications are also relevant where not only toxic, but also explosive or corrosive gases, such as ammonia NH₃, have to be detected.

Especially for ammonia (NH₃) there are already numerous applications in industry and nature.

For example, ammonia is used as a refrigerant in cold stores, breweries and slaughterhouses. It can also be used in large refrigeration plants. In the middle of the 20th century, ammonia was often replaced by chlorofluorocarbons (CFCs), which in turn are banned today. Nevertheless, ammonia has always been able to maintain its important role in industrial refrigeration because of its good thermodynamic properties.

Despite the fact that ammonia is often produced synthetically for use in refrigeration processes, it is referred to as a natural refrigerant. NH₃ is mostly produced during the decomposition of organic, nitrogenous materials. Nowadays, it is used as a refrigerant in large refrigeration systems for cold stores and in the air conditioning of airports, office buildings, production halls or sports facilities.

However, ammonia is corrosive, especially to copper materials. Piping in a system with ammonia as a refrigerant must therefore be made of steel. Since ammonia is also toxic and combustible to a certain extent, special safety regulations are required for the construction, operation and maintenance of these systems.

In concentrated form, ammonia vapors can cause eye and respiratory irritation; in elevated concentrations, mucous membranes and lungs can be damaged and, in the worst case, death can result. Furthermore, ammonia is classified as hazardous to water. It is easily soluble in water, such that penetration into the soil and the associated damage to groundwater must be avoided at all costs.

In addition, ammonia is explosive (ignition temperature at approx. 630° C.).

For the above reasons, it is important to detect a possible leakage of ammonia at an early stage. Due to its high sensitivity, PAS offers an excellent possibility to continuously monitor ammonia concentrations. Several devices are known from the prior art for this purpose.

In Peng et al. 2016, a sensor is disclosed that can detect ammonia in high temperature environments. A quantum cascade laser is used, which irradiates a cylindrical measurement chamber with a length of about 1.8 m. Furthermore, the measurement chamber itself is heated and a flow is generated inside it by supplying air from the environment. In addition, other compounds such as CH₄ (methane) and 1% NH₃/Ar (ammonia/argon) are introduced to control the flow within the chamber. At the end of the resonator is a detector that measures the signal strength of the quantum cascade laser. If there is a higher percentage of ammonia in the air introduced into the measurement chamber, this will absorb the beams from the quantum cascade laser. Thus, a weaker signal is also registered at the detector. With a measurement chamber of about 1.8 m in length, the apparatus is designed for industrial use and cannot be used flexibly. In addition, other components are added, such as thermocouples that measure the temperature distribution, windows coated with BaF₂ (barium fluoride) located at the ends of the resonator, or a heat jacket for the resonator. This makes the construction of the apparatus costly and complicates the design.

In Schilt et al. 2004, a CO₂ laser (carbon dioxide laser) irradiates the photoacoustic measuring cell. This comprises a cylindrical resonator and two buffer volumes, with the two buffer volumes acting as acoustic filters. A microphone is located at the end of the resonator. Furthermore, there is a semiconductor detector that measures the intensity of the laser beams. The measuring principle is the same as in Peng et al. 2016. If there are parts or molecules of ammonia in the beam path of the CO₂ laser, part of the laser radiation is absorbed. If there is no ammonia in the resonator, the measured pressure signal is maximum. A disadvantage results from the openings located at the two buffer volumes. Through these openings, other gases can in principle diffuse into the resonator, such that the measurement signal could be distorted.

In Bonilla-Manrique et al. 2019, a resonant gas cell is described that also includes two buffers and a cylindrical resonator, with the cylindrical resonator connecting the two buffers. The resonator has a length of 88 mm, and the two buffers each have a length of 44 mm, such that overall the device has a dimension of 176 mm. A microphone and a thin diaphragm are placed on the resonator to act as acoustic detectors. These are placed centrally on the resonator, with the microphone brought in through the resonator and the diaphragm attached to the opposite side from the outside. The photoacoustic effect also causes the diaphragm to oscillate. In the experimental setup, both the gas inlet, which is externalized by one of the two buffers, and the diaphragm are irradiated with laser beams. In this process, the measuring cell is already filled with 5000 ppm NH₃. Consequently, the apparatus of Bonilla-Manrique et al. 2019 also has macroscopic dimensions. In addition, it is not guaranteed that the measurement signal remains undistorted by the entry of other molecules, such as CO₂ (carbon dioxide) and H₂O (water), which could absorb the laser beams.

In light of the prior art, there is thus an interest in alternative apparatuses and/or methods for reliably hermetically sealing potentially toxic, corrosive, and/or explosive gases, into a chamber or a measuring cell, which have more extensive applications due to miniaturization.

U.S. Pat. No. 6,124,145 discloses a method by which gas, in particular CO₂, can be filled within two or more wafers. In this process, a first wafer, in which a cavity is introduced, is placed in a bonding chamber which is filled with the gas which is also to be located within the wafers. The second wafer is then bonded to the first wafer within the bonding chamber, creating a chamber or cell consisting of two wafers containing gas. However, this method is not readily suitable for the enclosure of corrosive or explosive gases, such as ammonia.

On the one hand, high temperatures are required for bonding. This means that gases which are flammable or even explosive at the corresponding bonding temperatures, such as ammonia, cannot be enclosed in the chamber. Otherwise, they would damage and, in the worst case, destroy the wafers or even the bonding chamber itself. In addition, with this method, it is not readily possible to form chambers from wafers that have electronic circuitry or MEMS devices, such as sensors, and then fill them with corrosive gases, such as ammonia. This is because the corrosive nature of ammonia would damage the corresponding electronic circuitry or MEMS device. In addition, the bonding process itself takes a certain amount of time and the conditions (temperatures, etc.) favor reactivity of the corrosive gases.

In the prior art, further methods as well as apparatuses are known which pursue the objective of transferring a gas into a miniaturized system.

For example, US 2018/0339900 A1 discloses a method for producing a MEMS device in which at least two sensors are located. The first sensor is preferably a rotation rate sensor, while the second sensor is preferably an acceleration sensor. The two sensors are formed in a wafer stack, but in separate regions. US 2018/0339900 A1 aims to prevent gases such as H₂ (hydrogen) or light noble gases, such as helium and neon, from diffusing through oxide layers and other layers at the occurring temperatures. For example, H₂ can diffuse from the accelerometer into the rotation rate sensor. To solve the problem, the production process first provides a MEMS wafer and a cap wafer, forms MEMS structures in the MEMS wafer for the two sensors, and then hermetically seals the MEMS wafer with the cap wafer. After sealing the two wafers, a first access hole is formed and then a first pressure is transferred into the cavity of the first sensor and finally the access hole is sealed. An analogous method is used for the second sensor. This is intended to allow two different internal pressures to be present in the cavities. In particular, it is also envisaged that after bonding H₂ is removed from the cavity of the second sensor (accelerometer) in order to introduce, for example, oxygen, ozone and/or a defined plasma. The formation of the access holes is performed by a laser. Sealing of the access holes is also performed with the aid of a laser.

US 2014/0038364 A1 discloses a method for encapsulating a microelectronic apparatus. The microelectronic apparatus is located on a first substrate and is bonded to a second substrate in a bonding chamber. The second substrate has a cavity such that after bonding, the microelectronic apparatus is located within the wafer stack. The gases to be injected into the cavity are noble gases. The second substrate has a region that is permeable with respect to the noble gases. Here, a layer that is non-permeable with respect to the noble gas which is to be introduced into the cavity is coated on the second substrate and then openings are formed thereon. In order to hermetically seal the noble gas, another layer is applied which is impermeable to the injected helium. A way to introduce gases more reactive than the described noble gases is not disclosed.

US 2020/0057031 A1 discloses a detector module for a photoacoustic gas sensor. The detector module is constructed such that a first substrate and a second substrate can be bonded together, and a recess can be filled with a reference gas in an airtight manner. The reference gas can be introduced into the recess in a reference gas atmosphere during bonding, or after bonding by forming a through hole in the first or second substrate, which is subsequently sealed. The reference gas is selected from a group comprising CO₂, NO_{X}, H₂O, O₂, N₂, CH₄ or alcohol. Filling the recess with a gas within a coating chamber is not described.

Also disclosed in US 2021/0055207 A1 is a detector cell for a photoacoustic gas sensor. Here, a gas atmosphere of a gas to be enclosed is produced and can be enclosed in a cavity during bonding.

US 2019/0353157 A1 discloses a miniature transport apparatus that can be used as a fluid control and/or for performing pressurization. The miniature transport apparatus and a miniature valve apparatus can be assembled, whereupon a gas can be introduced through an inlet. Through a piezoelectric actuator, the gas can flow through a plurality of pressure chambers and continuously flow in a transport direction. The gas can be released by a user determining the amount of gas or when the ambient pressure increases.

US 2007/0295456 A1 describes a material for bonding wafers. The bonding material is characterized by containing electrically conductive particles in addition to an insulating adhesive capability. It is further disclosed that air can be exchanged for a gas to be encapsulated in a bonding chamber, particularly for the operation of a MEMS device. The gases disclosed therein are not explosive, but inert.

US 2003/0183916 A1 discloses a method for packaging a MEMS device. In one embodiment, a sealing process may be performed in a controlled environment such that the cavity contains the desired ambient gas at a desired pressure. To this end, it is described that the openings are located far enough from the MEMS device so as not to damage it. A cover or sealing component (patch) is also disclosed to seal the openings.

US 2020/0198964 A1 deals with an encapsulation process for mounting a MEMS device within a wafer stack. Here, the openings can be sealed by a hole seal layer, whereby this is to be made possible by coating itself.

A safe, reliable production method for introducing and hermetically sealing corrosive and/or explosive gases into a MEMS cell without damaging MEMS devices or electronic circuitry within the MEMS cell is unknown. In particular, reliable and safe introduction of corrosive and/or explosive gases during the production of photoacoustic gas sensors is not apparent from the prior art. Thus, there is a need to make the introduction of gases into MEMS cells more efficient and safer for users.

### Objective of the Invention

The objective of the invention is to provide an apparatus as well as a method for its production which eliminate the disadvantages of the prior art. In particular, one objective of the invention is to enable PAS (photoacoustic spectroscopy) of corrosive and/or explosive gases by means of an apparatus that can be produced reliably and safely, which is characterized by a compact design and hermetic enclosure of the corrosive and/or explosive gases. The production method should also be simple, inexpensive and suitable for mass production to enable applications in a wide range of fields.

### SUMMARY OF THE INVENTION

The objective of the invention is solved by the features of the independent claims. Preferred embodiments of the invention are described in the dependent claims.

In a first aspect, the invention relates to a method for producing a gas-filled reference chamber within which a MEMS device and/or electronic circuit is present, comprising the following steps:
a) providing a first and a second wafer, wherein at least one of the first wafer and the second wafer has a cavity, and wherein a MEMS device and/or an electronic circuit is present on the first and/or second wafer,
b) bonding the first wafer to the second wafer within a bonding chamber to form a volume which can be filled with reference gas, wherein after bonding an opening remains in a region where the two wafers are in contact, or an opening is made in the first and/or second wafer before or after bonding,
c) flooding a reference gas into the reference chamber via the opening within a coating system,
d) sealing the opening of the reference chamber within the coating system.

The method according to the invention differs from U.S. Pat. No. 6,124,145 in that the gas to be introduced into the reference chamber is not in the bonding chamber during the bonding process. This prior art method significantly limits the choice of gases to be included in the reference chamber. This is because high temperatures occur during the bonding process. Depending on which bonding method is used, a temperature range from 250° C. up to 1000° C. is possible. Gases that are flammable or even explosive at these temperatures and the corresponding pressure conditions could not be introduced using the method from U.S. Pat. No. 6,124,145. If this were done, the entire experimental apparatus, in particular the bonding chamber, could be damaged or even destroyed. In particular, the method according to the invention can introduce ammonia into the reference chamber, the ignition temperature of which is 630° C.

The method according to the invention also allows gases that have a corrosive effect to be introduced and enclosed in the reference chamber. This is particularly crucial if MEMS devices and/or electronic circuits are present in the reference chamber. With the method known from U.S. Pat. No. 6,124,145, it is not possible to enclose gases having a corrosive effect in the reference chamber without damaging any MEMS devices and/or electronic circuits that may be present. In the case of using the method known from U.S. Pat. No. 6,124,145, the MEMS devices and/or electronic circuitry would be surrounded by a high amount of the corrosive gas, since the corrosive gas is flooded within the entire bonding chamber.

In particular, in U.S. Pat. No. 6,124,145, the bonding process takes place after the bonding chamber is filled with the gas to be enclosed. Because the bonding process takes a certain time, the MEMS device and/or the electronic circuit would be surrounded by the corrosive gas during the time required for bonding, while at the same time oxygen, which is in the bonding chamber, can also promote the reaction. Thus, the MEMS device and/or electronic circuit could be damaged by the high amount of corrosive gas and by the dwell time that it would be exposed to the corrosive gas and that the bonding requires.

The method according to the invention also differs from US 2014/0038364 A1, in particular in that the reference gas is introduced inside a coating chamber. In contrast, in US 2014/0028264 A1 the gas is introduced into the cavity in the bonding chamber. However, this considerably limits the choice of gases to be introduced, since during bonding there are temperatures at which explosive and/or reactive gases can carry out an undesirable reaction, such as an explosion. In US 2014/0028264 A1, for this reason, only noble gases, which are inert, are used as gases for introduction into the cavity of the MEMS cell. According to the invention, however, the introduction of the reference gas is carried out in a coating chamber. Advantageously, this also allows gases to be introduced which—unlike helium, for example—are flammable or even explosive in a bonding chamber at the corresponding bonding temperatures, such as ammonia. Consequently, the method according to the invention achieves a significant improvement over the prior art, since it is possible to introduce explosive and/or corrosive gases safely into the reference chamber and to seal them hermetically.

Furthermore, in the method according to the invention, the reference gas can preferably be filled directly into the volume of the reference chamber, whereby the reference gas is flooded in a coating chamber, in which the reference gas is then immediately sealed. Thus, the reference gas can preferably enter the volume of the reference chamber by diffusion—as a naturally occurring physical process due to Brownian molecular motion. In contrast, in US 2018/0339900 A1, an exchange process takes place for filling a volume in which one of the two sensors described therein is located. US 2018/033990 A1 discloses that, for example, H₂ is removed from the cavity of the second sensor and subsequently filled with oxygen, ozone, and/or a defined plasma, resulting in an exchange of gases. In particular, the gases mentioned in US 2018/033990 A1 may at least partially penetrate the surface of the MEMS element to react with the hydrogen or, if adsorbed by the surface, reduce the discharge energy of the hydrogen dissolved in the solid. Such a bonding reaction or exchange is avoided in the method according to the invention.

Furthermore, in US 2018/033990 A1, no filling of the sensor cavity takes place within a coating system, so that the coating system could be used to seal the openings of a reference chamber. Instead, the opening is sealed by means of a laser.

The disadvantages of the prior art are circumvented or eliminated by the method according to the invention. In the method according to the invention, a MEMS cell with an opening is provided, which is then filled with the gas to be enclosed. In this method, the reference chamber is first formed using two wafers. This is performed by means of a bonding process within a bonding chamber. An opening into the volume of the reference chamber can remain after bonding. However, the opening can also be made in one of the two wafers before or after bonding. After the bonding process, whereby the MEMS cell is formed, it is transferred to a coating system.

The coating system is then flooded with the gas to be enclosed in the MEMS cell so that it diffuses through the opening into the volume of the MEMS cell. In a next step, the opening is sealed and hermetically sealed. In particular, ammonia, which has an explosive and corrosive effect, can be enclosed in a MEMS cell by the method according to the invention. However, other gases that have such aggravating properties can also be enclosed in the MEMS cell by means of this method.

Advantageously, the method according to the invention can be used in particular to enclose corrosive and/or explosive gases in the MEMS cell without damaging or destroying MEMS devices and/or electronic circuits present therein. This is due to the fact that the introduction of the gas into the MEMS cell is more controlled, since on the one hand the flooding takes place downstream of the bonding process in a coating system and on the other hand the opening can be designed with smaller dimensions or additional sealing mechanisms can be provided. Thus, the gas can be introduced into a MEMS cell in an extremely controlled manner in terms of timing, concentration and duration.

In addition, less reactive conditions, in particular a lower temperature, are present inside the coating system, which is flooded with the gas to be enclosed, than inside the bonding chamber.

For the purposes of the invention, a MEMS cell preferably refers to a device which comprises two or more wafers and within which a MEMS device is present. In this context, the term MEMS cell may be construed as a generic term. A MEMS cell may include one or more openings that may be sealed. A MEMS cell may also be used as a reference chamber. The term MEMS cell frequently appears in connection with MEMS-based technologies and is familiar to persons skilled in the art.

For purposes of the invention, the reference chamber refers to a cavity formed by two or more wafers and comprising a volume formed by the two or more wafers. In other words, two or more wafers form a volume and the entirety of the wafers and the resulting volume are preferably comprised by the reference chamber. Preferably, the reference chamber is fillable with gas. Preferably, this may mean that the reference chamber has one or more openings which are present for filling the volume of the reference chamber. In order to preferably keep or enclose the gas within the reference chamber, the opening is arranged to be resealable. Advantageously, no gas exchange with the environment is thereby possible. The gas to be introduced or already introduced into the reference chamber is also referred to as the reference gas.

Preferably, a MEMS device and/or an electronic circuit is located within the reference chamber. For the purposes of the invention, a MEMS device is a part or component based on MEMS technology. MEMS stands for the English term microelectromechanical system, i.e. a microsystem, whereby a compact (micrometer range) design is achieved with simultaneously excellent functionality at increasingly lower production costs. A MEMS device can be, for example, a MEMS sensor or even a MEMS actuator. Many MEMS devices are known in the prior art. Advantageously, the method according to the invention allows a wide variety of MEMS devices to be placed in a reference chamber and filled with corrosive and/or explosive gases without damaging them.

Within the meaning of the invention, an electronic circuit refers to a combination of individual electrical or electromechanical elements to form a functional arrangement. Preferably, the electronic circuit allows data or electrical signals to be transmitted, received and/or processed.

The MEMS devices are often arranged on a substrate together with an electronic circuit for control and/or evaluation and are in contact with the latter via electrical connections, which are provided, for example, by wire bonds and/or conductor tracks laid out in the substrate. The substrate acts in particular as a carrier and can also realize electrical functions, e.g. providing electrical connections for the individual components.

Preferred electronic circuits comprise, without limitation, an integrated circuit (IC), an application specific integrated circuit (ASIC), a programmable logic device (PLD), a field programmable gate array (FPGA), a microprocessor, a microcomputer, a programmable logic controller, and/or other electronic, preferably programmable, circuitry.

In a preferred embodiment, two wafers are initially provided, wherein at least the first wafer and/or the second wafer has a cavity, and wherein a MEMS device and/or an electronic circuit is present on the first and/or the second wafer.

For the purposes of the invention, a cavity preferably refers to an indentation or depression in a wafer. Advantageously, the presence of one or more cavities on the first and/or second wafer may result in a suitable volume within the reference chamber by bonding the two wafers. Preferably, the cavities of the first and/or the second wafer form the reference chamber after bonding of both wafers.

A wafer can, for example, denote a circular or square disc with a thickness in the millimeter or submillimeter range. Wafers are typically made from monocrystalline or polycrystalline (semiconductor) blanks, known as ingots, and usually serve as substrates for e.g. coatings or components, in particular MEMS devices and/or electronic circuits. The use of the term substrate for the wafer is also known in the prior art, where substrate preferably refers to the material to be treated. For the purposes of the invention, the terms wafer and substrate may be used interchangeably.

In a preferred embodiment, the two wafers comprise materials selected from the group consisting of monocrystalline silicon, polysilicon, silicon dioxide, silicon carbide, silicon germanium, silicon nitride, nitride, germanium, carbons, gallium arsenide, gallium nitride, indium phosphide, and/or glass.

These materials are particularly easy and inexpensive to process in semiconductor and/or microsystem technology and are also well suited for mass production. Likewise, these materials are particularly suitable for doping and/or coating in order to achieve the desired electrical, thermal and/or optical properties in specific fields. The aforementioned materials offer a variety of advantages due to the usability of standardized manufacturing techniques, which are also particularly suitable for the integration of further components, such as electronic circuits.

Preferably, the MEMS device and/or electronic circuitry is found within the cavity of one of the two wafers.

In a preferred embodiment, the two wafers are formed into a reference chamber by bonding. Preferably, the bonding takes place within a bonding chamber. In the context of the invention, a bonding chamber refers to a device in which wafers are placed in order to be bonded together.

The bonding of wafers preferably describes a process step in semiconductor and microsystem technology in which two wafers or slices, made e.g. of silicon, quartz, glass and/or the aforementioned preferred substrate materials, are bonded together.

Preferably, various processes can be used for bonding. Preferably, these are also referred to as bonding processes or bonding methods within the meaning of the invention. Preferred bonding processes include direct bonding, anodic bonding, bonding with intermediate layers, glass frit bonding, adhesive bonding and/or selective bonding.

In direct bonding, especially of silicon wafers, hydrophilic and hydrophobic surfaces of the wafers are preferably brought into contact under high temperatures. Preferably, one wafer is pressed centrally against the other, advantageously creating a first contact point. This mechanical connection in the contact area is preferably based on hydrogen bonds and/or Van der Waals interactions. The contact area thus connected is preferably extended to the remaining wafer surface(s) by successively removing spacers initially present between these surfaces. Thereby, the process temperatures are preferably between 1000° C. and 1200° C. and a pressure is applied to the wafers, for example, in the order of 10 megapascals (MPa) to 25 MPa. Direct bonding can preferably be used for joining two silicon wafers and/or silicon dioxide wafers.

In anodic bonding, a glass with an increased Na+ ion concentration (preferably positively charged sodium ions) is used, which is preferably brought into contact with a silicon wafer. In this process, an electrical voltage is applied which is configured in particular to generate a negative polarity on the glass. Thus, preferably and in particular with the aid of an elevated process temperature, the sodium ions (Na+) diffuse to the electrode, whereby a space charge zone is preferably formed at the interface, which causes an increase in the electric field and generates Si—O—Si bonds. These bonds preferably extend successively to the entire interconnection surface between glass and silicon. In this way, glass and silicon wafers in particular can be bonded together. With appropriate adaptation of the process, bonding of two silicon layers and/or a silicon metal layer to a glass is also possible. Anodic bonding can preferably take place at temperatures of about 400° C., it can equally preferably take place at “low temperature” at about 180° C., preferably preserving the materials to be bonded. Preferably, various of the aforementioned materials can also be bonded.

Preferably, bonding processes with so-called intermediate layers between the wafers to be bonded can also be used, such as so-called eutectic bonding, which is preferably based on bonding through a eutectic alloy as an intermediate layer, e.g. Si—Au (silicon gold) or Ge—Al (germanium aluminum). A eutectic alloy is preferably an alloy whose constituents are mixed in such a ratio to each other that at a certain temperature the whole alloy becomes liquid or solid. Eutectic bonding can be used, for example, to bond two silicon wafers. Preferably, however, other aforementioned materials can also be bonded.

Glass frit bonding is also preferably based on the use of an intermediate layer between the wafers to be bonded, with the bond formation being carried out in particular by melting glass solders/glass frits. Glass solder preferably comprises a glass which has a low softening temperature, for example about 400° C. Glass frit preferably comprises superficially melted glass powder, the glass grains of which preferably bake or sinter together at least partially. This type of bonding can preferably bond silicon and/or silicon dioxide wafers together, but preferably also other aforementioned materials.

Adhesive bonding preferably describes a bond formation by an intermediate layer comprising adhesive. Adhesive bonding preferably allows various aforementioned materials to be bonded together.

Preferably, selective bonding can be performed by photolithography, etching, and/or lift-off processes.

By bonding the two wafers, which are preferably pre-processed to have cavities, the reference chamber can be easily produced.

The bonding of structures from pre-processed wafers allows the simple production of complex structures, which could be produced from a single wafer only at great expense. This allows the reference chamber to be produced without the need to laboriously carve out the raw material of the wafer in order to create the volume within the reference chamber.

In a preferred embodiment, the wafers have contact surfaces that are used in bonding the two wafers. Contact surfaces preferably comprise regions of the wafer that are provided or coated with a material that is required for bonding. The materials on the contact surfaces of the two wafers are preferably bonded or connected to create the reference chamber. Such a material may also be referred to as a bonding material in the context of the invention.

In a preferred embodiment, both wafers are bonded in such a way that an opening remains on a contact surface of the two wafers after bonding. The opening preferably results from the fact that no bonding takes place on the corresponding contact surface. Preferably, the opening is located in a lateral region of the reference chamber. Advantageously, a reference gas can be efficiently introduced into the reference chamber through the preferred opening in the lateral region of the reference chamber.

Within the meaning of the invention, the opening denotes an inlet into the volume of the reference chamber. Advantageously, the reference gas can be introduced into the volume of the reference chamber through or via the opening and preferably be hermetically sealed therein. In particular, the reference gas to be introduced can diffuse directly into the volume of the reference chamber through the opening. Diffusion is known as passive movement of particles of the reference gas to be introduced along a concentration gradient, which in this case exists at the beginning of the flooding of the reference gas into the coating chamber between the coating chamber and the volume of the reference chamber. The diffusion leads to an equalization of the concentrations, which is based on Brownian molecular motion. Advantageously, since diffusion is a passive transport process, no additional energy is required. In particular—in contrast to US 2018/0339900 A1—no chemical reaction or exchange is needed to introduce the gas into the reference chamber. Consequently, a particularly process-efficient introduction of the reference gas into the reference chamber within a coating system is advantageously made possible.

In another preferred embodiment, an opening is already present prior to bonding. Preferably, this is achieved by an etching process starting from an outer side of the first or the second wafer. Advantageously, this allows all contact surfaces to be used for bonding, so that the opening remains on the first or second wafer, such as was arranged before the bonding process and leads into the volume of the reference chamber.

In another preferred embodiment, the opening is formed after bonding the two wafers starting from the outside of the first or the second wafer. In this embodiment, too, all contact surfaces could advantageously be used for bonding. Preferably, the opening results after bonding via an etching process.

In a preferred embodiment, the reference chamber resulting after the bonding process is removed from the bonding chamber and placed within a coating system.

Within the meaning of the invention, a coating system preferably means a device that performs the production and processing of thin layers of different materials. Within the meaning of the invention, a thin layer or thin film preferably denotes a layer of a solid material in the micrometer or nanometer range.

In a preferred embodiment, the coating system is used to fill the reference chamber with the reference gas. For the purposes of the invention, the reference gas preferably refers to a gas that is introduced into the volume of the reference chamber and is preferably hermetically sealed or enclosed therein.

Preferably, the coating system is first flooded with the reference gas. The reference gas enters the volume of the reference chamber through the opening. Advantageously, the coating system does not have the temperature ranges that are absolutely necessary inside the bonding chamber for the purpose of bonding. Therefore, the reference gas can be a gas that would otherwise be flammable or explosive at the high temperatures present within the bonding chamber, introduced into the volume of the reference chamber. This expands the possibilities for gases that can be introduced into the reference chamber.

Advantageously, the reference chamber can also be flooded with corrosive gases in particular. The MEMS device and/or the electronic circuit within the reference chamber is brought into contact with the corrosive gas in a controlled manner via the opening. Since the subsequent step of hermetic sealing can take place immediately afterwards in the coating system, damage to the MEMS device and/or the electronic circuit by the corrosive gas is avoided.

In a preferred embodiment, after the process step of introducing the gas into the reference chamber, the latter is sealed within the coating system. Advantageously, there is no longer any exchange with the environment of the reference chamber after the sealing process. Thus, the introduced reference gas is present within the chamber and can no longer leave it or enter the environment.

For the purposes of the invention, the environment preferably means the totality of what is outside the reference chamber. Preferably, this includes the coating system and the reference gas introduced therein, which was flooded therewith in the previous process step.

Advantageously, after the reference chamber has been sealed, the reference gas can no longer escape from the reference chamber nor can reference gas from the environment enter the reference chamber. The method can thus be used to ensure that a precise amount of reference gas is present within the volume of the reference chamber.

Preferably, the reference chamber is sealed via a coating process within the coating chamber, wherein in particular the opening is sealed via a coating process. Preferably, at least the opening can be coated with a thin film for this purpose. A coating extending at least along the opening, preferably substantially along the opening, has proven advantageous in that a particularly precise seal is applied. Furthermore, coating material for sealing the opening is saved, such that a high degree of economy can be ensured by efficient use of material.

However, it may be preferred to coat substantially the entire reference chamber with a thin film to ensure a hermetic seal. Advantageously, a coating that extends essentially along or around the entire reference chamber provides a particularly reliable hermetic seal. Thus, on the one hand, a coating around the entire reference chamber ensures a particularly hermetic seal and, on the other hand, provides particularly robust protection against possible damage from the outside. This is particularly relevant for applications in which the gas is explosive and/or corrosive and which therefore have to meet the highest safety requirements. Also, by minimizing the risk that the introduced gas can escape, particularly accurate and thus reliable measurements are made possible, for example in the context of photoacoustic spectroscopy.

For the purposes of the invention, a hermetic seal preferably means a tight seal that prevents an exchange of substances with the environment of the reference chamber. In order to prevent the slightest contamination of the volume of the reference chamber, a hermetic seal is preferred. Apparatuses such as the reference chamber are preferably absolutely sealed against substance or matter exchange by means of a hermetic seal.

Within the meaning of the invention, contamination refers to an undesirable amount of substances or mixtures that can enter the volume of the reference chamber. Preferably, contamination is prevented by sealing the reference chamber.

In a preferred embodiment, the reference gas comprises corrosive and/or explosive gases, preferably methane, propane, propylene, silane, chlorosilane, aluminum triisopropanolate, hydrogen and/or oxygen, particularly preferably ammonia.

Advantageously, not only toxic but also explosive and/or corrosive gases can be introduced into the volume of the reference chamber by means of the method according to the invention. Advantageously, the possibilities for reference gases are thus extended. Hereby, a considerable improvement is achieved compared to the prior art, since the selection of gases is not limited or fixed to inert gases (e.g. noble gases as in US 2014/0038364 A1).

In the method known from U.S. Pat. No. 6,124,145, the gas is introduced inside the bonding chamber, which is to be enclosed inside the MEMS cell. However, high temperatures occur in various bonding processes. Therefore, gases that are flammable or explosive at those temperatures cannot be enclosed within the reference chamber using the known method. Otherwise, hazards such as explosion of the bonding chamber could result. This would also be disadvantageous for the user, who could come to harm in the event of an explosion. Advantageously, by the method according to the invention, flammable and/or explosive gases can also be enclosed in the reference chamber. Also in US 2014/0038364 A1, the gas (a noble gas) is introduced into the cavity within the bonding chamber. However, in a departure from the prior art, the gas is preferably introduced into the MEMS cell within the coating chamber according to the invention, in particular by flooding the coating chamber with the reference gas, for example by passive diffusion.

In addition, for various applications, it is desirable to include MEMS devices and/or electronic circuits within the reference chamber and fill it with a reference gas, e.g., for PAS (photoacoustic spectroscopy). However, with the method known from U.S. Pat. No. 6,124,145, no corrosive gas can be enclosed in the reference chamber in this case. This is because the bonding chamber is flooded with the gas to be enclosed. Therefore, the MEMS device and/or electronic circuit would initially be exposed to a high amount of the corrosive gas, which could result in damage to them. The time that the MEMS device and/or electronic circuit would be exposed to the corrosive gas also plays a role in this regard. The bonding process itself of the wafers also takes some time. By the time the bonding process is complete, the MEMS device and/or electronic circuit would be exposed to the corrosive gas. Therefore, during the time of the bonding process, the corrosive gas could damage or even destroy the MEMS device and/or electronic circuit.

With the method according to the invention, the disadvantages of the prior art are circumvented or eliminated. Thus, advantageously, explosive and/or corrosive gases can be introduced into the reference chamber and hermetically sealed off by means of the method according to the invention.

For the purposes of the invention, flammable or ignitable preferably refers to the property of a substance or a mixture having a low flash point. Preferably, the flash point of a substance denotes the lowest temperature at which an ignitable mixture can form over a substance. Preferably, gases or mixtures thereof are considered to be flammable if they have an explosion range in air at 20° C. and a standard pressure of 101.3 kPa (kilopascal).

For the purposes of the invention, an explosive gas means a gas or mixture which, when sufficiently energized, e.g. by a high temperature, undergoes a certain chemical reaction in which a high proportion of thermal energy can be developed. This results in a violent expanding effect which can cause considerable destruction. There is a danger to life if explosive substances or gases are handled improperly.

For purposes of the invention, a corrosive gas preferably refers to a gas that undergoes a chemical reaction with the reference chamber and/or its components, such as the MEMS device and/or electronic circuitry, and causes a measurable change as a result. This process is preferably referred to as corrosion for the purposes of the invention. Corrosion can result in degradation of the function of the reference chamber or the components of the reference chamber.

Advantageously, explosive and/or corrosive reference gases can preferably be introduced into the reference chamber by the method according to the invention. However, any other reference gas can also be introduced by the method according to the invention.

In a preferred embodiment, an inert gas, preferably nitrogen, is additionally introduced into the reference chamber via the opening to set a partial pressure of the reference gas within the reference chamber.

For the purposes of the invention, partial pressure is the partial pressure of a single component of a gas mixture. The partial pressure corresponds to the pressure which the individual gas component would exert if it were present alone in the volume concerned. The total pressure is composed additively of the partial pressures, i.e. the sum of all partial pressures is equal to the total pressure.

Advantageously, the amount or concentration of reference gas in the reference chamber in particular can be precisely specified by regulating the partial pressure of the reference gas. This is advantageous for certain applications of the reference chamber, e.g. as a sensor for the PAS. In the applications, the desired reference concentration or sensitivity can be predetermined by adjusting the concentration or amount of reference gas. Consequently, the quantity of the introduced gas can be optimized in a targeted and precise manner.

For the purposes of the invention, an inert gas is preferably a gas which is inert to reactions. The gas does not participate in chemical reactions or only does so to a minor degree. With respect to PAS applications, the inert gas should also have a different absorption characteristic in the relevant excitation region. Examples of inert gases include gases such as nitrogen or noble gases such as helium, neon, argon, krypton, xenon, or gaseous molecular compounds such as sulfur hexafluoride.

The aforementioned advantages of the invention are based on the fact that an opening remains on a contact surface of the two wafers after bonding, or an opening is made in the first and/or second wafer before or after bonding.

In a preferred embodiment, the first wafer and the second wafer have contact areas for bonding the first wafer to the second wafer, wherein a region of contact areas is not bonded, in order to form the opening.

Preferably, this forms an opening in the lateral region of the reference chamber. This advantageously allows good penetration of the reference gas into the reference chamber within the coating system.

Advantageously, with this embodiment, no further process steps are necessary to form an opening in the reference chamber. The opening is preferably already produced during the bonding process. The fact that no further process steps are required also eliminates the need for further material and structuring. The manufacturing costs and time are reduced. Advantageously, this results in higher process efficiency.

In a preferred embodiment, an opening remains on a contact surface of the two wafers after bonding, the opening having a cross-section from 1 μm² to 1000 μm², preferably 1 μm² to 100 μm², and a length of 1 μm to 1000 μm, preferably 10 μm to 500 μm.

Advantageously, the dimensions of the opening in this preferred embodiment result in a diffusion-inhibiting effect. In this context, diffusion within the meaning of the invention refers to the phenomenon whereby an equalization of concentration differences occurs without external influence. Initially, when the coating system is flooded with the reference gas, there is little to no gas within the volume of the reference chamber. Over time, the reference gas diffuses through the opening into the volume of the reference chamber. This is a passive physical process due to Brownian molecular motion. The process of flooding can be enhanced by introducing the reference gas into the coating system at an elevated pressure and/or concentration.

The preferred dimensioning as an essentially elongated opening results in essentially one-dimensional diffusion dynamics in which, after diffusing through the opening into the volume, the reference gas does not leave it or leaves it only over longer time constants.

The diffusion-inhibiting effect can be used, for example, to bridge intermediate times in the processing. For example, it may be preferable to first flood the reference chamber with a reference gas in the coating system, then to exchange the reference gas for a process gas inside the chamber and to seal the opening by means of a coating process. Due to the diffusion-inhibiting effect, the reference gas does not escape during the exchange of the gases or the execution of the coating process.

By dimensioning the opening accordingly, it is advantageously possible to set the time span over which the reference gas can diffuse into the reference chamber and the time span over which diffusion out is reliably prevented. The above-mentioned preferred dimensions represent a good compromise in this respect.

In a preferred embodiment, before or after bonding the first wafer to the second wafer, the opening is formed starting from an outer side to an inner side of the first wafer or the second wafer, preferably by means of an etching process.

Advantageously, the position and/or dimensioning of the opening can be precisely selected by inserting the opening before or after. For example, the positioning can be chosen in dependence of a MEMS device and/or an electrical circuit in the reference chamber in order to avoid interference. For example, it may be preferred that the opening is arranged in the center of the outer side of the first or the second wafer starting from the outer side into the inner side of the reference chamber.

In terms of the invention, an etching process preferably comprises dry etching, wet chemical etching and/or plasma etching, in particular Reactive Ion Etching, Reactive Ion Deep Etching (Bosch process).

An etching process preferably refers to the removal of material from a surface. The removal can take the form of depressions that leave cavities on wafers.

In semiconductor technology and microsystems engineering, dry etching is a group of erosive microstructure processes that are not based on wet chemical reactions (such as wet chemical etching, chemical-mechanical polishing). The material is removed either by accelerated particles or with the aid of plasma-activated gases. Chemical and physical effects are utilized depending on the process.

Dry etching processes can be classified into three groups. Firstly, the physical dry etching processes, they are based on material removal by bombardment with particles, and secondly, chemical dry etching processes, they are based on a chemical reaction of a mostly plasma-active gas. The third group, the physical-chemical dry etching processes, combines processes that use both mechanisms of action and is thus able to minimize the disadvantages of the first two groups.

In wet chemical etching, an etch-resistant mask is transferred into the wafer through a chemical ablation process.

Plasma etching is a material-removing, plasma-assisted dry etching process. In plasma etching, a distinction is made between etch removal due to a chemical reaction and physical removal of the surface due to ion bombardment.

In chemical plasma etching, material removal occurs through a chemical reaction. Therefore, it is generally isotropic and also very material selective due to its chemical nature. Physical plasma etching, also called plasma-assisted ion etching, is a physical process. In this process, a certain preferential direction in the etching attack can occur, therefore the processes may exhibit anisotropy in material removal. In physical plasma etching, non-reactive ions are generated in the plasma. An applied electric field accelerates these ions onto a surface, removing portions of the surface. This process is typically used to remove the natural oxide on silicon wafers.

Reactive ion etching (RIE) is an ion-assisted reactive etching process. Due to the good controllability of the etching behavior, RIE is a process for the fabrication of topographic structures for microsystems and nanosystems technology. The process allows both isotropic (direction-independent) and anisotropic etching by chemical-physical ablation. The etching is performed by charged particles (ions) generated in a gas plasma. An appropriate masking (e.g. produced by photolithography) of the surface gives the shape of the structures.

Deep reactive ion etching (DRIE) is a further development of reactive ion etching (RIE) and a highly anisotropic dry etching process for the fabrication of microstructures in wafers with an aspect ratio (ratio of depth to width) of up to 50:1, whereby structure depths of several hundred micrometers can be achieved. The DRIE process is a two-step, alternating dry etch process in which etching and passivation steps alternate. The aim is to etch as anisotropically as possible, i.e. directionally, perpendicular to the wafer surface. In this way, for example, very narrow trenches can be etched.

The aforementioned etching processes are known to the person skilled in the art. Depending on the desired opening and/or wafers provided, advantageous processes can be selected to ensure efficient performance.

In a preferred embodiment, a valve is present at the end of the opening in the first or second wafer, the valve preferably being located in the volume of the reference chamber after bonding of the first wafer to the second wafer at the end of the opening starting from the outside of the first wafer or the second wafer. The end of the opening preferably designates the transition from the opening in the first or second wafer to the (reference) volume of the reference chamber.

A valve at this position can be used to control the diffusion of the reference gas, with which the coating chamber is flooded, into the volume of the reference chamber.

With the attachment of a valve, automatic sealing of the reference gas is advantageously possible. In particular, an escape of reference gas that has already diffused into the volume can be prevented without restricting the dynamics of the flooding.

In contrast to a diffusion-inhibiting effect, for example through an elongated opening with essentially one-dimensional diffusion dynamics, a valve can be used to block diffusion from the reference chamber in a more targeted manner, while diffusion into the reference chamber can take place rapidly without hindrance.

By means of a valve, efficient flooding can thus take place, which allows, for example, the reference gas to be exchanged for a process gas within the chamber and the opening to be sealed by means of a coating process. Due to the provision of a valve, the reference gas cannot escape during this time either.

In addition, the provision of a valve may advantageously allow more precise regulation of the amount and/or concentration of the reference gas to be introduced into the reference chamber.

Preferably, a valve refers to a component that is used for directional control or shut-off of a flow of fluids. Preferably, a valve can be formed by, for example, a flexible shutter—for example based on a thin film structure—which unidirectionally allows diffusion of the reference gas into the reaction chamber during flooding, while preventing diffusion out of the diffusion chamber after flooding.

Preferably, before bonding and before forming the opening of the first or the second wafer, a material layer—preferably for forming a flexible seal—can be applied to the opposite side of a wafer from which an opening is introduced (e.g. etched). Preferably, the material layer can be structured as a valve in the further process. In this case, the opening of the first or the second wafer can be formed first and then the material layer can be structured to form a valve. A reversed sequence is also possible.

In a preferred embodiment, the material layer that is to form the valve is structured prior to bonding. Structures formed in this process can include contact pads, conductive paths, alignments, corners, edges, depressions, sinks and/or holes.

Preferably, the material layer can first be applied to the entire surface of one side of the wafer. In particular, the structuring can restrict the material layer to an area around the opening such that the existing area of the material layer can act as a valve at the end of the opening.

Preferably, the opening in the wafer is formed on the opposite of the material layer structured as the valve by means of an etching process. The skilled person can select suitable etching processes for this purpose to ensure that the valve is not damaged in the process.

Preferably, the first wafer is then bonded, comprising an opening with a valve and the second wafer. Bonding takes place in such a way that the valve is located at the end of the opening and within the volume of the reference chamber, so that the described functionality is achieved.

In a preferred embodiment, after the first wafer is bonded to the second wafer, the reference chamber in the coating system is flooded with the reference gas, the gas entering the volume of the reference chamber through the opening and via the valve.

In a preferred embodiment, the valve (or the material layer to be structured) comprises a soft metal. Preferably, for the purposes of the invention, soft metals are to be defined as metals which have a lower hardness than iron (e.g. in a Brinell hardness test in accordance with DIN EN ISO 6506-1 to 4). Preferred soft metals are non-ferrous metals selected from the group consisting of lead, gold, indium, copper, platinum, silver, zinc, tin or compounds thereof, particularly preferably aluminum or compounds thereof.

Advantageously, a soft metal can on the one hand be precisely structured by simple means, such that the process can be configured in a time-saving and cost-effective manner. On the other hand, soft metal is suitable as a valve for use according to the invention due to its flexibility.

In addition to the choice of material, the dimensioning of the material layer also plays a role in this respect.

Preferably, the material layer to be structured as a valve or the valve is designed as a thin-film structure. Thin-film structure preferably means a layer thickness of less than 100 μm, preferably less than 10 μm.

In particular, by using a thin-film structure, preferably comprising soft metal, good flexibility of the valve can be ensured to regulate the diffusion process accordingly.

The reference gas enters the valve through the opening in the first or second wafer and exerts a pressure against the valve. Depending on the flexibility of the valve, at a certain point the pressure exerted is high enough to open the valve in the direction of the volume of the reference chamber and allow the gas to pass.

In a preferred embodiment, after flooding the reference gas into the reference chamber, the solder is melted to seal the opening.

The solder is preferably placed near the opening of the reference chamber for this purpose, preferably before bonding.

The application of a solder in microsystem technology is a well-known procedure and does not involve any difficulties for the person skilled in the art.

Preferably, the solder is placed near the opening of the reference chamber before the reference gas is flooded in the coating system and the reference gas diffuses into the volume of the reference chamber via the opening.

Advantageously, in this embodiment, the reference gas can diffuse particularly efficiently into the volume of the reference chamber prior to melting of the solder. Since in this embodiment neither a diffusion-limiting effect of an elongated opening nor a valve has to be provided, which may have a residual (albeit small) resistance to diffusion.

Preferably, the melting of the solder seals the opening of the reference chamber. The melting of the solder is a known process step for the person skilled in the art, whereby the melting temperature is selected depending on the material to be melted.

Preferably, as the solder melts, a portion of the material comprising the solder enters the opening and seals its cross-section. The solder or melted material can fill the entire opening or only part of it, as long as the cross-section is sealed tightly. The size of the solder is adapted to the opening to be sealed. It may be preferred that the entire molten material is used to seal the opening or only a portion thereof.

Placing the solder in the vicinity of the opening, preferably means positioning it in a spatial proximity which ensures that the molten solder can also flow into the opening. Proximity can mean, for example, a distance of less than 100 μm, preferably less than 10 μm.

In a preferred embodiment, the solder comprises a fusible material selected from the group comprising lead, tin, zinc, silver, copper, alloys thereof, and/or compounds thereof.

Preferably, the solder is brought to its melting temperature during melting. The melting temperature is the temperature at which the solder is converted from a solid to a liquid state. Preferably, the solder has a melting temperature at which the reference gas does not react flammably and/or explosively, so that any sparks that may occur would not lead to hazards.

Advantageously, the above preferred materials for the solder have melting temperatures below the temperature at which the preferred reference gases react flammably and/or explosively.

In a preferred embodiment, the opening is sealed by means of a coating process within the coating system, preferably by spray coating, mist coating, and/or steam coating.

The coating process preferably seals the reference chamber well. Advantageously, this means that the reference gas can no longer leave the reference chamber and permanent sealing is ensured.

In cases where the valve is at the end of the opening, the melting of the solder already causes a first sealing of the opening. The additional application of a cover layer stabilizes the seal over the long term and ensures hermetic sealing of the reference chamber over the lifetime of the reference chamber.

Various coating processes can be used to apply a cover coat.

A spray coating refers in particular to a two-dimensional application of a cover layer, whereby the cover layer is preferably pressurized before spraying (e.g. higher than the prevailing ambient pressure) so that fine particles/aerosols of the cover layer and/or a foam are formed. In this way, a particularly fine coating can be achieved which covers all sprayed areas, even if, for example, these have surfaces which are at an unfavorable angle to the spraying direction. Even surfaces/areas that are at an angle to one another can thus preferably be covered directly.

Preferably, a liquid cover layer is atomized and applied to the surface under pressure higher than ambient pressure.

The spray coating is preferably a spray lacquer. The spray coating can also be a vapor phase deposition.

A mist coating preferably comprises a coating by fine droplets of the masking layer, which are finely dispersed in an atmosphere (preferably a gas). A vapor coating preferably involves coating by a covering layer to be applied in vapor form, or gaseous form.

In a preferred embodiment, the coating system comprises a physical coating system or chemical coating system, preferably plasma-enhanced chemical coating system, low-pressure chemical and/or epitaxial coating system.

A physical coating system preferably refers to a coating system that performs coating by physical vapor deposition (PVD). Physical vapor deposition, or rarely also physical steam deposition, refers to a group of vacuum-based coating processes or thin-film technologies. Unlike chemical vapor deposition processes, physical vapor deposition is used to convert the starting material into the gaseous phase. The gaseous material is then applied to the wafer to be coated, where it condenses and forms the target layer.

Arc evaporation or arc PVD is a coating process from the group of physical vapor deposition. In this process, an arc burns between the chamber in which the process takes place and the target, which is at negative potential. This arc melts and evaporates the target material, which is later deposited on a workpiece (the wafer), for example. The target acts as the cathode, the chamber wall of the vacuum chamber or a defined electrode as the anode. In the process, a large portion (up to 90%) of the evaporated material is ionized. The material vapor (target material) spreads radially from the target, similar to thermal evaporation. Since a negative potential is also applied to the wafer, the ionized material vapor is additionally accelerated towards the substrate. The material vapor condenses on the wafer surface.

An epitaxial coating system is preferably a system in which an epitaxial process is used, preferably molecular beam epitaxy. Molecular beam epitaxy (MBE) is a physical vapor deposition (PVD) process to produce crystalline thin films (or film systems). Epitaxy means that the crystal structure of the growing layer adapts to that of the substrate, as long as the physical properties of the two substances do not differ too greatly.

MBE requires an ultra-high vacuum to avoid contamination by residual gas atoms. During the growth process, however, the pressure rises into the high vacuum range due to effusion. The materials of which the layer is to consist are heated in evaporation crucibles and reach the wafer as a directed molecular beam (without collisions with the background gas). This is also heated, thus allowing the layer to grow in an orderly manner.

Sputtering, also known as cathode sputtering, is a physical process in which atoms are released from a solid (target) by bombardment with high-energy ions (mainly noble gas ions) and pass into the gas phase.

A chemical coating system preferably refers to a coating system that performs coatings via chemical vapor deposition (CVD). In chemical vapor deposition, a solid component is deposited on the heated surface of a wafer as a result of a chemical reaction from the gas phase. The prerequisite for this is that volatile compounds of the layer components exist, which deposit the solid layer at a certain reaction temperature. The chemical vapor deposition process is characterized by at least one reaction at the surface of the workpiece to be coated. This reaction must involve at least one gaseous starting compound (reactant) and at least two reaction products—at least one of which must be in the solid phase. In order to promote those reactions on the surface over competing gas-phase reactions and thus avoid the formation of solid particles, chemical vapor deposition processes are usually operated at reduced pressure (typically: 1-1000 Pa). A special feature of the process is conformal coating deposition, whereby even the finest recesses in wafers, for example, are uniformly coated.

Chemical vapor deposition also includes atomic layer deposition (ALD). Atomic layer deposition is a highly modified chemical vapor deposition (CVD) process with two or more cyclically performed self-limiting surface reactions. The material to be deposited is chemically bonded to one or more carrier gases, called precursors. These precursors are alternately fed into a reaction chamber where they are made to react with the wafer, whereupon the material bonded in the gas deposits onto the substrate material. The resulting layers usually have a polycrystalline or amorphous structure.

Plasma-enhanced chemical vapor deposition (PECVD) preferably denotes a system that uses the plasma-enhanced or plasma-assisted chemical vapor deposition process. Plasma-enhanced chemical vapor deposition is a special form of chemical vapor deposition (CVD) in which the chemical deposition is supported by a plasma. The plasma can burn directly at the wafer to be coated (direct plasma method) or in a separate chamber (remote plasma method).

While in CVD the dissociation of the molecules of the gas occurs as a result of external supply of heat as well as the released energy of the subsequent chemical reactions, in PECVD this task is performed by accelerated electrons in the plasma. In addition to the radicals formed in this way, ions are also generated in a plasma, which together with the radicals cause the layer deposition on the wafer. The gas temperature in the plasma usually increases by only a few hundred degrees Celsius, which means that, in contrast to CVD, more temperature-sensitive materials can also be coated. In the direct plasma method, a strong electric field is applied between the wafer to be coated and a counter-electrode, which ignites a plasma. In the remote plasma method, the plasma is arranged so that it has no direct contact with the substrate. This offers advantages in terms of selective excitation of individual components of a process gas mixture and reduces the possibility of plasma damage to the wafer surface by the ions.

Low pressure chemical vapor deposition (LPCVD) is the process commonly used in semiconductor technology for the deposition of silicon oxide, silicon nitride and polysilicon, as well as metals.

In a preferred embodiment, a cover layer is applied within the coating system at least over a region of the opening, preferably around the entire reference chamber, wherein the material for the cover layer is preferably a nitride, preferably a silicon nitride, silicon carbonitride, silicon oxynitride, titanium nitride and/or tantalum nitride, an oxide, preferably a silicon oxide, aluminum oxide, silicon dioxide, titanium dioxide or tantalum oxide, or a metal, preferably an aluminum and/or a noble metal, preferably gold, platinum, iridium, palladium, osmium, silver, rhodium and/or ruthenium.

The cover layer over the entire reference chamber advantageously provides a particularly good hermetic seal of the reference chamber. This means that the reference gas remains particularly well sealed in the volume of the reference chamber. This ensures with a particularly high degree of reliability that gas from the volume of the reference chamber cannot leave it after sealing, especially if the cover layer has been coated substantially along or around the reference chamber.

Advantageously, the reference chamber is also protected from the outside, i.e. from its environment, and in particular according to the production method additionally by the cover layer. This also minimizes the risk of external damage, e.g. through contamination of a fluid and through a mechanical effect.

On the one hand, the above-mentioned materials can be easily processed and thus used to apply a cover layer. In addition, due to their blocking properties, the materials represent a reliable and also long-term stable barrier against an escape of the reference gas and/or an entry of foreign gases.

In a preferred embodiment, a process gas is introduced into the coating system to seal the opening and form a cover layer, wherein the process gas is introduced into the reference chamber after flooding a reference gas, or wherein a material for forming the cover layer is selected such that the reference gas can simultaneously serve as the process gas.

Within the meaning of the invention, the process gas preferably denotes a gas which is used to ensure that the coating is effected by the cover layer in the subsequent process step. The application or adhesion of the cover layer to the reference chamber occurs via a physical and/or chemical reaction. Preferably, in this physical and/or chemical reaction, the process gas helps or enables the cover layer to be coated on the reference chamber.

In particular, in the case of flooding an additional process gas with the reference gas, a diffusion-limiting or diffusion-blocking opening is desirable. Advantageously, this is achieved by the method according to the invention with the attachment of a diffusion-blocking solder or valve or a diffusion-limiting opening in the lateral region of the reference chamber during the bonding process with the corresponding dimensions. Advantageously, the reference gas can first preferably enter the volume of the reference chamber via these openings. Subsequently, a gas exchange within the coating system can follow, such that after the introduction of a process gas the coating process takes place. Both during the (at least partial) gas exchange from a reference gas to a process gas, the diffusion-limiting or diffusion-blocking opening ensures that the reference gas does not escape. For certain applications, it may also be preferred that no additional process gas is flooded into the coating system, but that the reference gas corresponds to the process gas. Preferably, this is the case with ammonia as the reference gas, which can serve as the process gas in particular for a cover layer comprising nitride compounds.

Advantageously, in this case there is no need for a gas exchange in the coating system. Rather, the coating step can follow seamlessly after the reference chamber has been flooded with reference gas. In preferred embodiments, ammonia is the process gas that also functions as the reference gas, i.e. as the gas for filling the reference chamber. Advantageously, by using ammonia as the process gas, a cover layer comprising nitride compounds can serve particularly efficiently for hermetic sealing of the reference gas, since it is not necessary to introduce another gas into the coating chamber as a process gas for bonding between the cover layer and the reference chamber. With regard to the retention of the reference gas within the coating system, the desired concentration of the reference gas within the chamber can be set particularly precisely. Undesired diffusion of a process gas different from the reference gas into the chamber is inherently prevented by a targeted selection of process parameters.

In another embodiment, the MEMS device is a MEMS sensor and/or MEMS actuator and/or the electronic circuit comprises a processor, a switch, transistors, and/or transducers.

The MEMS sensor or MEMS actuator refers in particular to a sensor or actuator in the form of a microsystem (Micro-Electro-Mechanical System, abbreviated MEMS). A microsystem is in particular a miniaturized device, assembly and/or component, where the components have dimensions in the micrometer range (1 μm to 1000 μm) or smaller and interact as a system. The MEMS sensor is, for example, a sound detector.

In another embodiment, the MEMS device comprises a sound pressure detector, wherein the sound pressure detector preferably comprises a capacitively or optically readable piezoelectric, piezoresistive and/or magnetic bar and/or a capacitive, piezoelectric, piezoresistive and/or optical microphone.

The embodiment is particularly suitable for use of the reference chamber in the PAS, wherein the sound pressure waves can be detected directly in the reference chamber by the sound pressure detector.

A piezoelectric beam is preferably a vibratable structure, in particular in the form of a bending beam, which comprises a piezoelectric material, e.g. in the form of an actuator.

It may be preferred that the bending beam is passive, which preferably means that it is caused to oscillate by the sound pressure waves. These in turn generate a voltage through the deformation of the piezoelectric material, which is based on the piezoelectric effect. The (direct) piezoelectric effect preferably describes the occurrence of an electrical voltage and/or a change in impedance on a solid made of corresponding material when it is elastically deformed. The voltage can be tapped, for example, by suitable contacting and read out by a corresponding electronic circuit.

It may also be preferred that the bending beam is active, which means in particular that it is caused to oscillate due to the inverse piezoelectric effect. The piezoelectric effect preferably describes the deformation of a material when an electric voltage and/or an electric field is applied, whereby a force can be exerted in particular by the material. The sound pressure waves can preferably cause a variation in the damping of the vibrating beam, which can be measured, e.g. by a change in the resonant frequency of the vibrating beam.

A bar that vibrates passively due to sound pressure waves can preferably also be read out, e.g. by capacitive, magnetic and/or piezoresistive methods. The idea is preferably also that an electrically readable change is generated by the vibration, e.g. based on a changing magnetic flux through a resonating magnet, by a changing capacitance between a vibrating and a fixed electrode and/or by a changing electrical resistance in a piezoresistive material.

A microphone preferably comprises a vibrationally mounted diaphragm which is excited to vibrate by sound pressure waves, which in turn can be read out electrically, similar to the beam described above. Capacitive, piezoelectric and/or piezoresistive measurement methods of the vibration design can also be used.

Preferably, an optical microphone can also be used, whereby these vibrations can preferably be converted into an optical signal by reflection, e.g. of a laser beam on the membrane, which is read out, e.g. in an interferometric arrangement.

In a further aspect, the invention relates to a reference chamber producible by the method according to the invention.

The invention thus preferably relates to a reference chamber producible by a method comprising
a) Providing a first and second wafer, wherein at least one of the first wafer and the second wafer includes a cavity, and wherein a MEMS device and/or an electronic circuit is present on at least one of the first wafer and the second wafer
b) Bonding the first wafer to the second wafer within a bonding chamber to form a volume which can be filled with reference gas, wherein an opening remains on a contact surface of the two wafers after bonding, or an opening is made in the first and/or second wafer before or after bonding
c) Flooding a reference gas into the reference chamber via the opening within a coating system
d) Closing the opening of the reference chamber within the coating system.

The average person skilled in the art will recognize that technical features, definitions and advantages of preferred embodiments which apply to the method according to the invention for producing the reference chamber apply equally to the producible reference chamber and vice versa.

In a preferred embodiment of the invention, the reference chamber has a height from 10 μm to 2 mm, preferably from 50 μm to 1 mm, more preferably from 100 μm to 500 μm.

In this way, a flat and compact design, in particular a low overall height of the reference chamber, can advantageously be achieved.

In another preferred embodiment, the reference chamber has a length and/or width from 100 μm to 5 mm, preferably from 200 μm to 3 mm, more preferably from 500 μm to 2 mm.

With these dimensions, it is advantageously possible to introduce sufficient volume of reference gas into the volume of the reference chamber. At the same time, these dimensions also advantageously allow a MEMS device, preferably a MEMS sensor, particularly preferably a sound pressure detector, to be installed, preferably for use in the PAS.

In another aspect, the invention relates to a manufacturing method for a photoacoustic gas sensor comprising the steps of:
Producing a reference chamber filled with the reference gas by means of a production method according to the invention or preferred embodiments thereof, wherein a MEMS sensor is present within the reference chamber as a MEMS device,
Providing a modulable emitter,
Arrangement of the reference chamber filled with the reference gas and the modulable emitter,

wherein the reference chamber is present in the beam path of the emitter such that the emitter can excite the reference gas in the reference chamber by means of modulable emittable radiation to form sound pressure waves which are detectable by means of the MEMS sensor.

In another aspect, the invention relates to a photoacoustic gas sensor comprising
a modulable emitter
a reference chamber filled with the reference gas, wherein a MEMS sensor is present within the reference chamber,

wherein the reference chamber is present in the beam path of the emitter such that the emitter can excite the reference gas in the reference chamber by means of modulable emittable radiation to form sound pressure waves which are detectable by means of the MEMS sensor, wherein the reference chamber filled with the reference gas is producible by a method according to the foregoing.

The average person skilled in the art will recognize that technical features, definitions and advantages of preferred embodiments disclosed for the method according to the invention for producing the reference chamber or the reference chamber producible thereby apply equally to a photoacoustic gas sensor comprising such a reference chamber or to a gas sensor production method, and vice versa.

In particular, the invention enables the provision of a miniaturized photoacoustic gas sensor which also safely and hermetically encloses corrosive or explosive gases (such as ammonia) as reference gases and thus enables monitoring of the occurrence of such hazardous gases in the ambient air. The method according to the invention thereby ensures that sensitive components of the photoacoustic gas sensor (such as the MEMS sensor) are not attacked during the enclosure of the reference gas. Also, leakage of the potentially hazardous gases from the reference chamber is prevented by means of hermetic sealing, which also ensures a high degree of safety from potential damage due to the compact arrangement.

In a preferred embodiment, the reference chamber of the photoacoustic gas sensor forms a sealed system which is filled with the reference gas and wherein a gas to be analyzed, preferably ambient air, is present in the optical path between the emitter and the reference chamber so that the proportion of the reference gas in the gas to be analyzed can be measured on the basis of the formation of sound pressure waves in the reference chamber.

The basic features and essential components of a photoacoustic gas sensor are known to the person skilled in the art. A modulable emitter generates electromagnetic radiation and is preferably arranged and configured such that the radiation emitted by the infrared emitter substantially or at least partially impinges on the gas in the reference chamber.

If the modulated irradiation takes place at a wavelength corresponding to the absorption spectrum of a molecule of a gas component present in the gas mixture, modulated absorption takes place, which leads to heating and cooling processes whose time scales reflect the modulation frequency of the radiation. According to the photoacoustic effect, the heating and cooling processes lead to expansions and contractions of the gas component causing it to form sound pressure waves with substantially the modulation frequency. The sound pressure waves are also referred to as PAS signals and can be measured by means of a sensor, for example a sound detector. The power of the sound waves is preferably directly proportional to the concentration of the absorbing gas component.

The term gas component is preferably understood to mean the proportion of chemically (and spectroscopically) identical gas molecules (e.g. ammonia) in a gas mixture, while the gas mixture means the totality or mixture of a plurality of (preferably different) gas components (e.g. air).

Various emitters are preferably considered as radiation sources for the above applications. For example, narrowband laser sources can be used. These advantageously allow the use of high radiation intensities and can be modulated with standard components for photoacoustic spectroscopy, preferably at high frequencies.

Preferably, broadband emitters can also be used. Advantageously, these have a broad spectrum which can be further selected, for example, by using (tunable) filters.

In a preferred embodiment of the invention, the modulable emitter is a thermal emitter and comprises a heating element, the heating element comprising a substrate on which is deposited, at least in part, a heatable layer of a conductive material on which contacts for a current and/or voltage source are present.

In this context, the heating element comprises a heatable layer made of a conductive material which produces joule heating when an electric current flows through it. In particular, the heating element comprises a substrate on which the heatable layer is present. The substrate preferably forms the base of the heating element. In this context, the substrate may also comprise other elements of the IR emitter, such as base elements and/or housing elements, at least in part. Advantageously, the substrate can be suitably formed by established process steps, in particular from semiconductor and/or microsystem manufacturing. The aforementioned materials are particularly easy and inexpensive to process in semiconductor and/or microsystem production and are also well suited for mass production. Likewise, these materials are particularly suitable for doping and/or coating in order to achieve the desired electrical, thermal and/or radiation properties in specific fields.

The substrate may preferably be selected from a group comprising silicon, monocrystalline silicon, polysilicon, silicon dioxide, silicon carbide, silicon germanium, silicon nitride, nitride, germanium, carbon, gallium arsenide, gallium nitride, and/or indium phosphide.

The conductive material used for forming the heatable layer can preferably be selected from the group comprising platinum, tungsten, (doped) tin oxide, monocrystalline silicon, polysilicon, molybdenum, titanium, tantalum, titanium-tungsten alloy, metal silicide, aluminum, graphite and/or copper. On the one hand, these materials exhibit the desired thermal, electrical, mechanical and/or radiation properties, and on the other hand, they are particularly easy and inexpensive to process.

The (micro-)heating element is preferably at least partially free-standing and allows, e.g. within the IR emitter, thermal expansions as a result of strong temperature changes as well as translational movements. Partially free-standing means that it is at least partially not positively and/or frictionally connected to other elements of the emitter at the interfaces and therefore has a degree of freedom of movement in a direction substantially perpendicular to the interface.

The emitter is modulable, which means that the intensity of the emitted radiation, preferably the intensity of the beam can be changed in a controllable manner over time. The modulation shall preferably cause a temporal change of the intensity as a measurable variable. This means, for example, that there is a difference in intensity over time between the weakest intensity measured within the measurement period and the strongest intensity measured within the same period that is greater than the sensitivity of an instrument typically used to measure or determine intensity for the radiation spectrum and the application. Preferably, the difference is significantly greater than a factor of 2, more preferably 4, 6 or 8 between the strongest and weakest adjustable intensity. Particularly preferably, the intensity of the modulated beam is modulated for one or more predetermined resonant wavelengths.

Preferably, direct modulation can be performed by varying the current supply. In the case of a thermal emitter, such modulation is usually limited to a specific range of a modulation spectrum due to thermal time constants, e.g. in the range of an order of magnitude of up to 100 Hz. In the case of a laser or an LED, for example, much higher modulation rates are preferably possible, e.g. in the kHz range and beyond.

Modulation of the infrared emitter can preferably likewise be accomplished by external modulation, e.g., by use of a rotating chopper wheel and/or an electro-optic modulator.

A modulable emitter preferably refers to a device that emits electromagnetic radiation in a wavelength range within a specific spectrum. In particular, the spectrum is selected to correspond to the preferred field of application of the emitter, namely photoacoustic spectroscopy. In particular, a vibrational excitation of the gas molecules to be spectroscoped and/or detected is preferred, which, depending on the gas molecules, corresponds to a preferred spectral range.

The emission of the IR emitter is preferably in the form of a beam, which is oriented linearly in a preferred direction. The term beam is intended to describe the preferably focused portion of the radiation along the preferred beam direction of the emitter which is emitted by the emitter, in particular with the areas of greatest intensity along this direction defining the beam. Intensity is preferably defined as area power density and preferably has the unit of watts per square meter, abbreviated as W/m².

Additional components, such as lenses, may be integrated into the emitter or attached externally to provide for beam focusing or collimation. A person skilled in the art knows how to shape the emission profile of the radiation source by designing the emitter as well as by using additional components in such a way that a desired beam profile as well as a desired beam direction result. Preferably, the modulable emitter can do without additional lenses, or can be a system comprising a radiation source and at least one lens for collimating the beam.

Preferably, the reference chamber is located in the beam path of the emitter. Preferably, this means that the intensity of the beam is substantially or at least partially incident on the side of the reference chamber facing the emitter. Partially preferably means at least 40%, preferably at least 50%, 60% or more. In particular, it means that the region of maximum intensity of the beam impinges on the detection chamber. Preferably, it means that the beam is focused and/or collimated such that a substantial portion of the intensity impinges on the side facing the emitter. A preferred example is a Gaussian beam, which in particular has a transverse profile according to a Gaussian curve. Along the beam, the z-axis is preferably defined by the distance with the maximum intensity. The beam radius w at the “height” z of the beam is thereby preferably defined as the distance to the z-axis at which the intensity has fallen to 1/e² (preferably about 13.5%). Following this definition, it is preferred that “the reference chamber is in the path of the emitter” means that substantially all of the beam radius is incident on the side of the reference chamber facing the emitter.

Preferably, the side of the reference chamber facing the emitter is transparent to the emitted radiation, so that the radiation substantially reaches the interior of the chamber that can be filled with gas. Preferably, the side of the reference chamber facing the emitter in particular is also referred to as the irradiation surface.

The fact that the reference chamber is present in the beam path of the infrared emitter means in particular that the emitter can excite gas in the detection chamber by means of modulable emittable radiation to form sound pressure waves, since this is irradiated at least partially (preferably at least 40%, more preferably at least 50%, in particular at least 60%) and in particular a substantial part of the radiation reaches the volume which can be filled with gas inside the detection chamber. A substantial part means in particular at least 80%, more preferably 90% and in particular 95%.

Terms such as substantially, approximately, about, etc. preferably describe a tolerance range of less than ±20%, preferably less than ±10%, even more preferably less than ±5% and in particular less than ±1%. Indications of substantially, approximately, about, etc. always also disclose and include the exact value mentioned. The reference chamber contains a reference gas which is matched to the IR emitter in such a way that modulated IR radiation penetrating the reference chamber enables a PAS with the aid of the gas molecules of the reference gas there. If the measuring path between the infrared emitter and the reference chamber also contains a proportion of reference gas in the air to be analyzed (in particular ambient air), which absorbs the IR radiation, PAS takes place. This reduces the strength of the absorption in the reference chamber.

The magnitude of the reduction allows conclusions to be drawn about the concentration of the reference gas in the measurement path. Preferably, the formation of sound pressure waves in the reference chamber is smaller the more reference gas is present in the beam path outside the detection chamber, since absorption and excitation then already take place there. Preferably, a narrow-band IR emitter is used here so that, if possible, only the reference gas can be excited.

This measuring principle allows the smallest concentrations of molecules of a reference gas to be detected within the ambient air. The monitoring of toxic, corrosive or explosive gases, such as ammonia, is therefore particularly safe and reliable.

Advantageously, the measuring principle also inherently ensures an error control or an error alarm. Only if the gas sensor works correctly, a PAS signal is reliably detected which shows the expected maximum amplitudes in the absence of noticeable ammonia concentration in the ambient air. Limit values can be defined for the monitoring range, which correspond to permissible concentrations of ammonia.

If the sound detector, emitter or any other component is faulty, this is detected as a change in the expected PAS signal. A warning can be issued automatically. Depending on the deviation from the PAS signal, the warning message can refer to a presumably faulty function of the gas sensor and/or impermissible limit values.

The warning does not have to be issued by a WatchDog function or similar, but is inherent to the measuring principle. The absence of a warning and an undetected increase in potentially dangerous concentrations is effectively avoided.

Preferably, the gas sensor further comprises a control unit configured to control the modulable emitter and/or the MEMS sensor and to receive data from the modulable emitter and/or the MEMS sensor and, if necessary, to evaluate the data.

The control unit may preferably comprise a described electronic circuit located inside the reference chamber and connected to the MEMS sensor. Furthermore, it is preferred that the control unit comprises at least one (external) data processing unit (e.g. integrated circuit (IC), application specific integrated circuit (ASIC), programmable logic device (PLD), field programmable gate array (FPGA), microprocessor, microcomputer, programmable logic controller and/or other electronic, preferably programmable, circuit), which is located outside the reference chamber and connected to the electronic circuit inside the reference chamber.

For example, it may be preferred that the control unit on the one hand outputs electrical control signals by means of the external data processing unit, which control the modulable emitter and the MEMS sensor. On the other hand, an evaluation can be made of the measurement data recorded by the MEMS sensor (in particular measurement data on the PAS signal), preferably by means of the external data processing unit. The internal electronic circuit can also already perform a (pre-)evaluation of the measurement data of the MEMS sensor. However, it may also be preferred that the internal electronic circuitry essentially forwards the measurement data unprocessed to the external data processing unit for further processing and/or evaluation.

### DETAILED DESCRIPTION

In the following, the invention will be explained in more detail by means of examples, without being limited to them.

Short Description of the Images

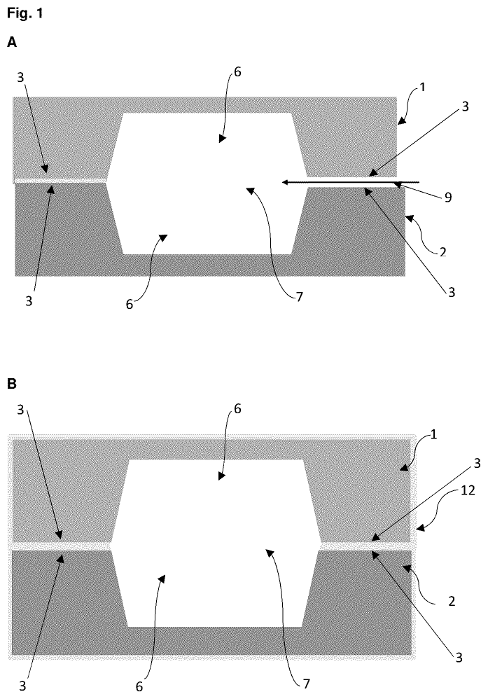

FIG. 1A-B Schematic overview of a first preferred embodiment of the method according to the invention for forming a reference chamber filled with reference gas in which an opening remains on the contact surfaces of the wafers after bonding.

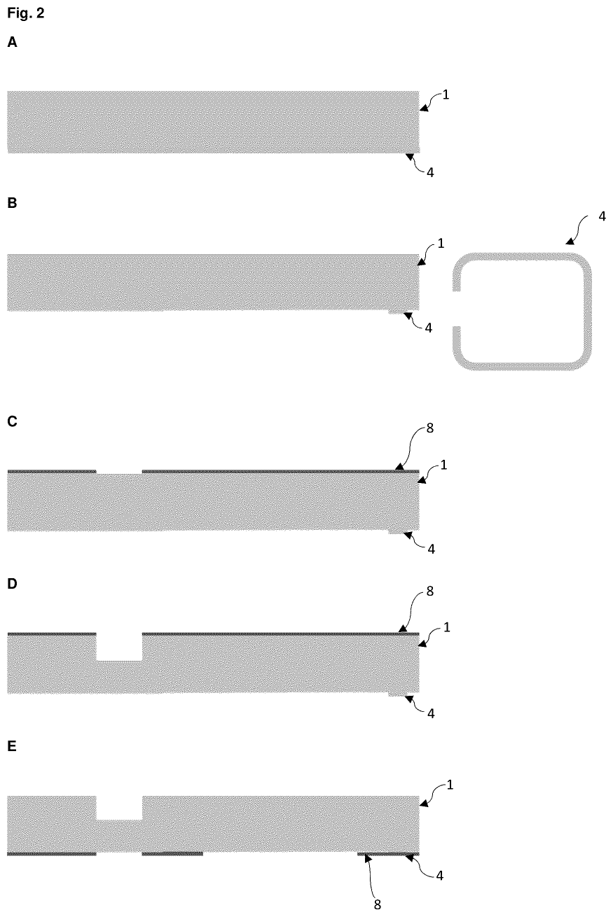

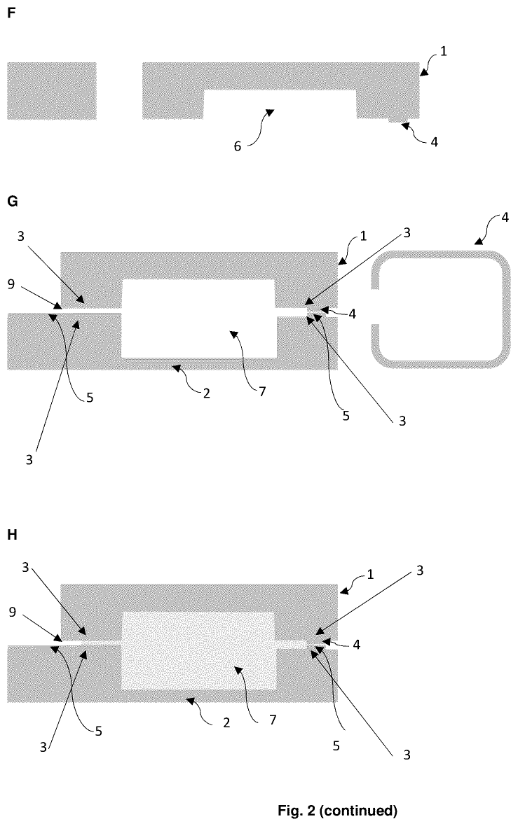

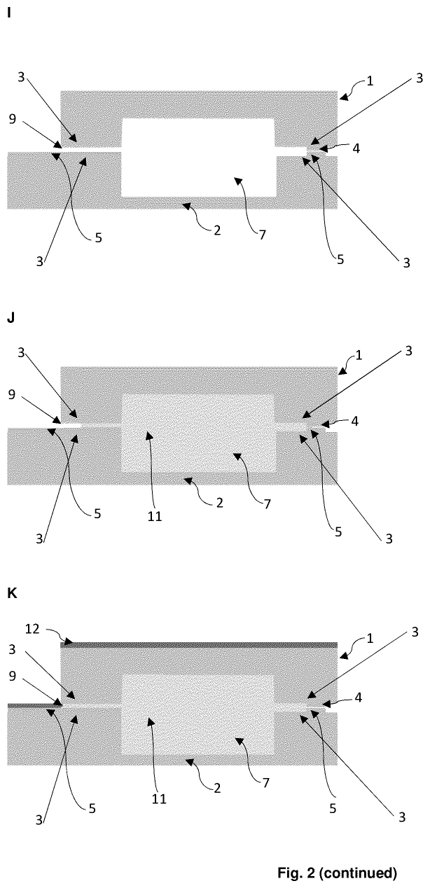

FIG. 2A-K Schematic illustration of preferred process steps of the first preferred embodiment of the method for producing a reference chamber filled with reference gas, in which an opening remains on the contact surfaces of the wafers after bonding.

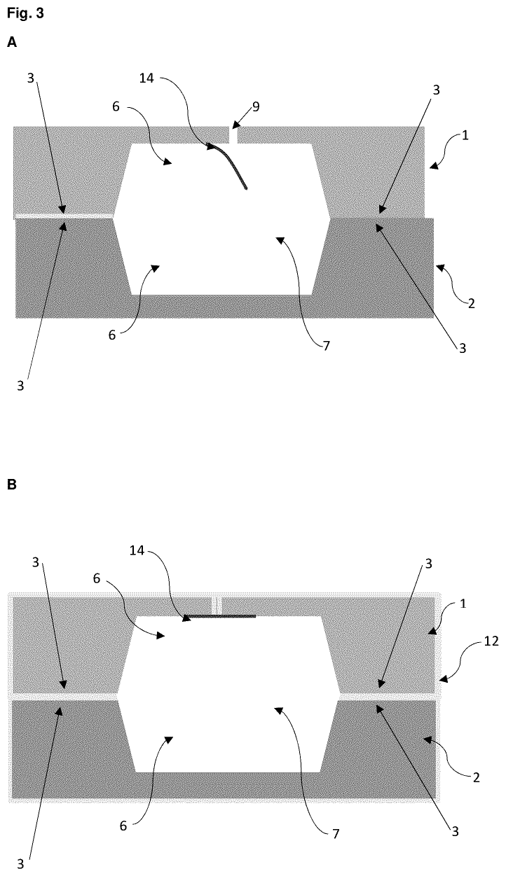

FIG. 3A-B Schematic overview of a second preferred embodiment of the method according to the invention for forming a reference chamber filled with reference gas, which exhibits a valve.

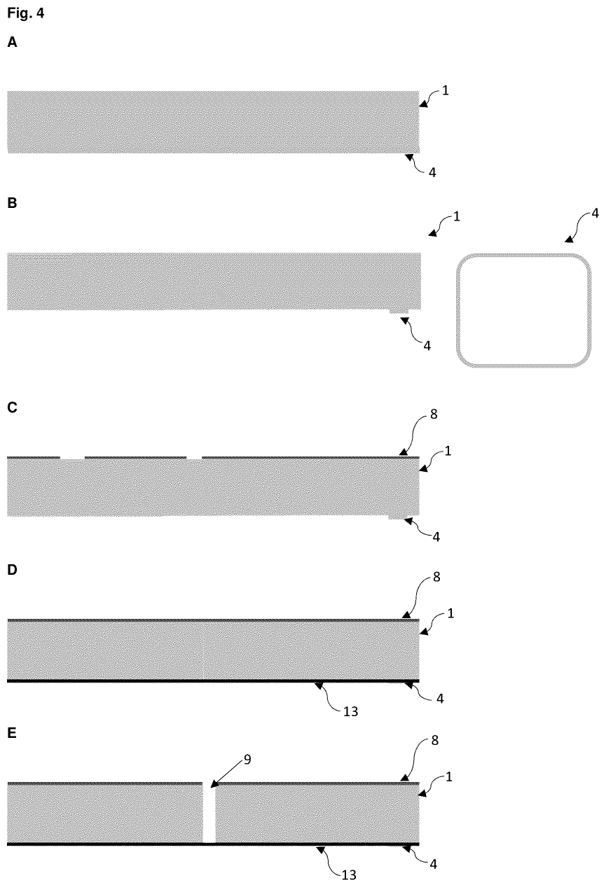

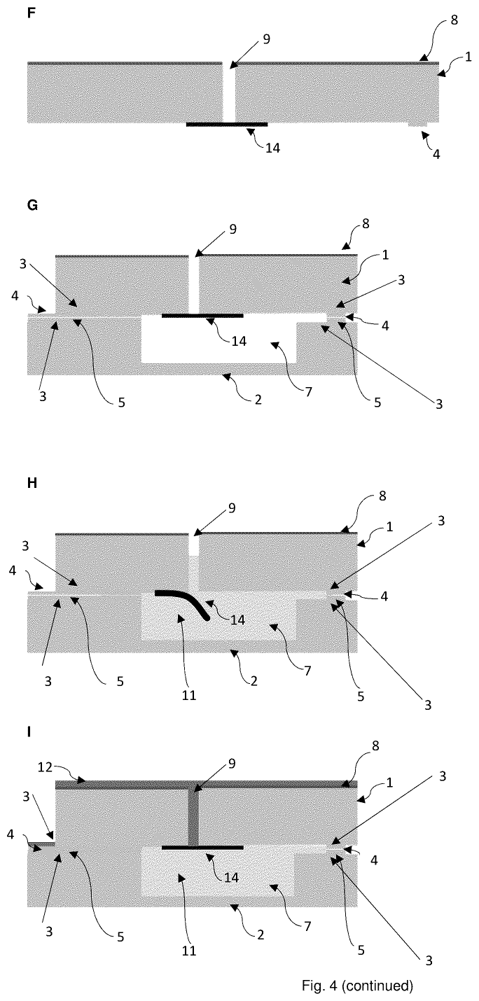

FIG. 4A-B Schematic illustration of preferred process steps of the second preferred embodiment of the method according to the invention for producing a reference chamber filled with reference gas, which exhibits a valve.

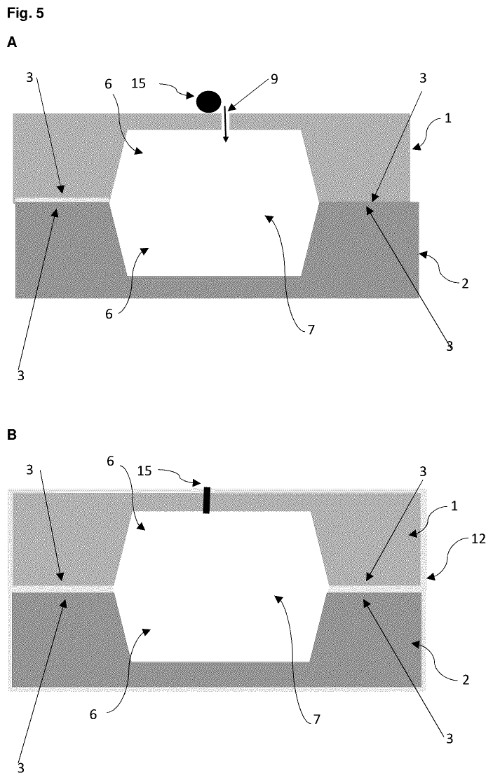

FIG. 5A-B Schematic overview of a third preferred embodiment of the method according to the invention for forming a reference chamber filled with reference gas, the opening of which is sealed with a thermal solder.

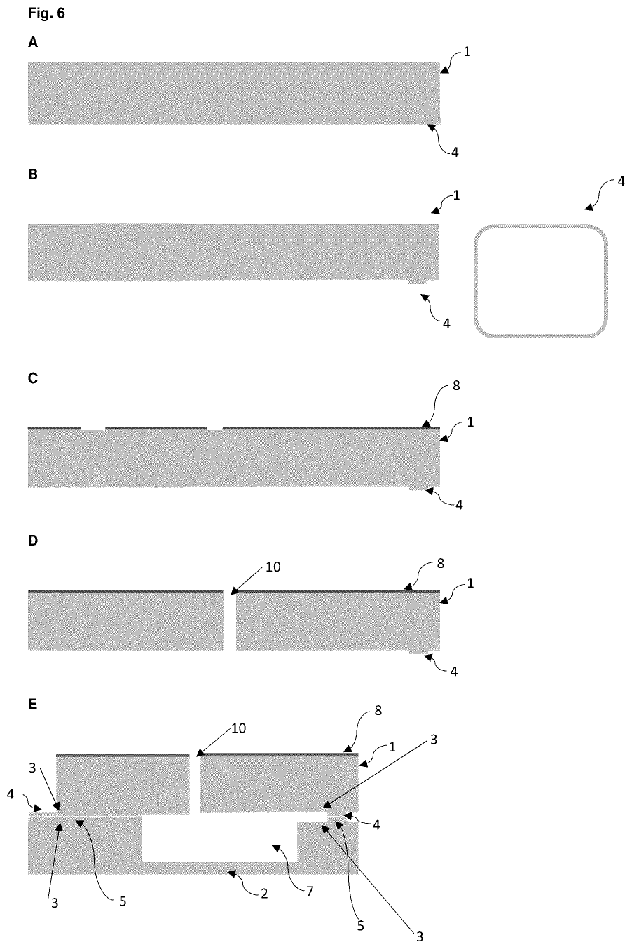

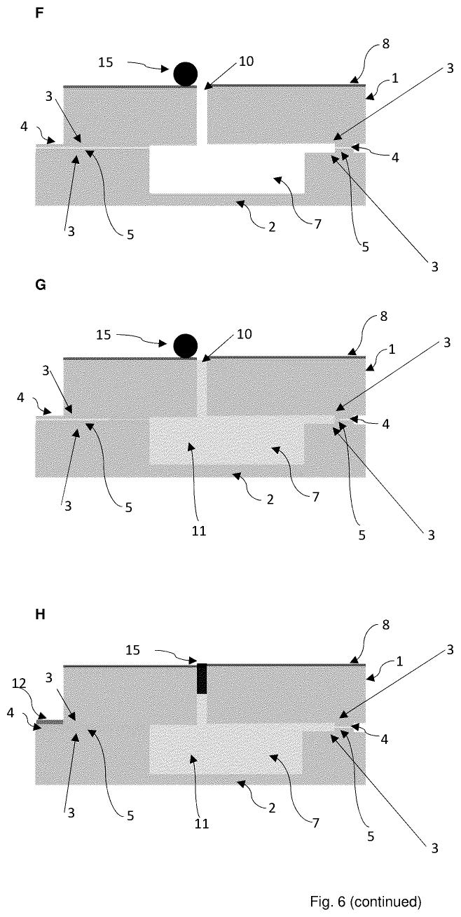

FIG. 6A-H Schematic illustration of preferred process steps of the third preferred embodiment of the method according to the invention for producing a reference chamber filled with reference gas, the opening of which is sealed with a thermal solder.

### DETAILED DESCRIPTION OF THE ILLUSTRATIONS

FIGS. 1A-B show a summary illustration of a first variant of the production method according to the invention.

A first wafer 1 and a second wafer 2 are provided, whereby both the first (upper) wafer 1 and the second (lower) wafer 2 each have a cavity 6. A MEMS device and/or an electronic circuit is present on the first 1 and/or second wafer 2 (for example within the cavities, but not shown).

The bonding of the first wafer 1 with the second wafer 2 takes place within a bonding chamber for forming a volume 7 which can be filled with reference gas 11, wherein an opening 9 remains on a contact surface 3 of the two wafers after bonding. The first wafer 1 and the second wafer 2 also preferably have contact surfaces 3 for this purpose, which are used for bonding the first wafer 1 to the second wafer 2, with a region on the contact surfaces 3 not being bonded in order to form the opening 9.

FIG. 1A illustrates on the right side the unbonded lateral region of the reference chamber, which allows an opening 9 to be provided. Flooding of a reference gas 11 into the reference chamber via the opening 9 can be performed as described within a coating system. In FIG. 1A, the flooding step is illustrated as an arrow.

In the preferred embodiment, the sealing of the opening 9 of the reference chamber within the coating system is performed by a coating process that applies a cover layer 12 at least over a region of the opening, as illustrated in FIG. 1B, preferably around the entire reference chamber. The cover layer 12 may preferably be a nitride that reliably hermetically seals the entire reference chamber.

FIG. 2A-K shows preferred process steps of a first variant of the method according to the invention for producing a reference chamber filled with reference gas 11, in which an opening remains on the contact surfaces 3 of the wafers after bonding.

As illustrated in FIG. 2A, in a first process step, the first wafer 1 can be sputtered on the rear side with a first bonding material 4. The first bonding material 4 can preferably be gold. Here, bonding material denotes a material which is preferably suitable for bonding.

FIG. 2 B illustrates a preferred structuring of the first bond material 4. The left-hand side shows a central cross-section through the reference chamber to be formed. The right-hand side additionally shows a top view. The structured first bonding material 4 forms an almost closed border, which however has a recess on the left side. The recess is not bonded, but serves to form the opening into the reference chamber.

A structuring of the first wafer 1 is performed by means of a photoresist 8 and etching processes, as illustrated in FIG. 2C to FIG. 2 F.

In FIG. 2 C, a photoresist 8 is applied to the front of the first wafer 1, leaving a region free for further processing. Said region of the first wafer 1 is etched via an etching process, preferably via deep reactive ion etching (DRIE), as shown in FIG. 2 D. The region of the first wafer 1 is then etched in the etching process. However, the first wafer is preferably not etched throughout. In FIG. 2 E, a photoresist 8 is applied to the rear side of the first wafer 1. It can be the same photoresist 8 as in the previous steps, or a different one. Starting from the rear side, an etching process (preferably DRIE) is performed again at the relevant location (see FIG. 2 F) to cut the first wafer 1 at the region previously etched on the front side. In addition, the rear-side etching process creates a cavity 6 in the first wafer 1, which can be used to form the volume 7 in the reaction chamber.

In FIG. 2 G, the first wafer 1 is bonded to the second wafer 2, on which a second bonding material 5 is located. The second wafer 2 also has a cavity 6 which is complementary to the cavity 6 of the first wafer 1. The second wafer 2 can be provided by analogous etching processes.

The second bonding material 5 can preferably be aluminum, copper and/or gold. The second bonding material 5 may, but need not, be present in a structured form. To avoid bonding at the opening 9 to be formed, it is sufficient that the first bonding material 4 of the first wafer 1 has a recess on the left side. Preferably, the first wafer 1 and the second wafer 2 are bonded together via thermo-compression bonding (TC—bonding for short). However, the region on the left-hand side is not bonded at contact surfaces 3.

In this preferred embodiment of the process, the region at non-bonded contact surfaces is used as opening 9 to fill the reference chamber with a reference gas 11, e.g. ammonia. Thus, a reference chamber is produced which contains a volume 7 and has an opening 9. Thereby, the opening 9 is located in a lateral region of the reference chamber and is provided by the fact that no bonding process takes place in this region. In FIG. 2 G, the opening 9 can be seen in the lateral region of the reference chamber on the left. To the right of the illustration of the reference chamber, a top view of the first bonding material 4, preferably gold, is shown. Bonding processes take place in a bonding chamber, which is not illustrated.

In FIG. 2 H, the reference chamber is no longer located in the bonding chamber, but in a coating system, preferably in a PECVD system (Plasma-Enhanced Chemical Vapor Deposition). In this case, any gas with room pressure can initially be located in the volume 7 of the reference chamber, which in FIG. 2 I is pumped out within the coating system, so that a vacuum is then located in the volume 7 of the reference chamber. The person skilled in the art knows that in reality a vacuum is never absolute, but is characterized by a considerably lower pressure compared to atmospheric pressure under normal conditions.

In FIG. 2 J, the coating system is flooded with the reference gas 11 so that the reference gas 11, e.g. ammonia, enters the volume 7 of the reference chamber via the opening 9. In FIG. 2 K, the reference chamber is hermetically sealed within the coating system via a cover layer 12, in particular by depositing a nitride, as a result of which the opening 9 is also reliably sealed and therefore the reference gas 11 can no longer escape from the reference chamber.

FIG. 3A-B shows a summary illustration of a second variant of the method according to the invention for producing a reference chamber filled with reference gas 11. The first wafer 1 and the second wafer 2 are provided, both wafers 1 and 2 again exhibiting cavities 6. There is a MEMS device and/or an electronic circuit on the first 1 and/or the second wafer 2, e.g., within the cavities 6. However, these are not shown.

After bonding the two wafers 1 and 2, an opening 9 is etched into the first 1 or second wafer 2. A valve 14 is located at the end of the opening 9. The two wafers 1 and 2 are bonded together such that the valve 14 is located within the volume 7 of the reference chamber at the end of the opening 9. Preferably, the valve 14 is attached to the first 1 or the second wafer 2 before the bonding process. In contrast, during the bonding process itself, the contact surfaces 3 are used throughout to bond the first wafer 1 to the second wafer 2. After bonding the first wafer 1 with the second wafer 2, the reference chamber is brought out of the bonding chamber into the coating system, where it is flooded with the reference gas 11, the reference gas 11 entering the volume 7 of the reference chamber via the opening 9 and via the valve 14.

Finally, the cover layer 12, preferably with a nitride deposition, is used to hermetically seal the reference chamber, preferably over the entire region of the reference chamber.

This manufacturing process is particularly preferred if a process gas different from the reference gas 11 is used to apply the cover layer 12. Advantageously, the valve 14 already seals the reference gas 11 inside the reference chamber before coating with the cover layer 12, so that any gas exchange (from reference gas to process gas) cannot lead to contamination.

FIG. 4A-I show preferred process steps of the second variant of the method according to the invention for producing a reference chamber filled with reference gas 11.

In FIG. 4A, the first wafer 1 is coated on the rear side with a first bonding material 4. Preferably, the first bonding material 4 is gold and is coated onto the rear side of the first wafer 1 via a sputtering process.

In FIG. 4 B, the first bonding material 4 is patterned on the rear side of the first wafer 1. A top view of the first bonding material 4 is illustrated on the right. In FIG. 4 C, a photoresist 8 is applied to the front side of the first wafer 1. In FIG. 4 D, a material layer 13 is applied to the rear side of the first wafer 1. Preferably, a soft metal, especially preferably aluminum, is applied as a material layer 13 as a thin film to the back side of the first wafer 1 via a sputtering process. In FIG. 4 E, starting from the front side of the first wafer 1, an opening 9 is formed via an etching process, preferably via a dry etching process. In this process, the opening 9 is etched up to the material layer 13. Subsequently, in FIG. 4 F, the material layer 13 is structured to form a flexible valve 14.

In FIG. 4 G, the first wafer 1 is bonded to a second wafer 2, preferably via TC bonding (see above). The second bonding material 5 on the contact surfaces 3 of the second wafer 2 can preferably be gold, copper and/or aluminum. In FIG. 4 H, the reference chamber within a coating system, preferably within a PECVD system, is flooded with the reference gas 11 via the opening 9, wherein the valve 14 opens when the gas is introduced. In FIG. 4 I, the reference chamber is hermetically sealed via a cover layer 12, preferably via a nitride.

FIG. 5A-B shows a summary of a third variant of the production method according to the invention. Also in this third variant, the two wafers 1 and 2 have cavities 6, in which a MEMS device and/or an electronic circuit can be inserted. The MEMS device and/or the electronic circuit are not shown. The two wafers 1 and 2 are preferably bonded to each other at all contact surfaces 3 in a bonding chamber.

Preferably, the opening 9 is formed prior to bonding via an etching process, preferably dry etching. After bonding both wafers 1 and 2, a solder 15 is placed near the opening 9. After introducing the reference gas 11, e.g. ammonia, into the volume 7 of the reference chamber within the coating system, the solder 15 is melted so that it flows into the opening 9. The opening 9 is sealed as a result of the melting and the solder flowing into it. The reference chamber is hermetically sealed via a cover layer 12, preferably a nitride.

FIG. 6A-H shows preferred process steps of the third variant of the method according to the invention for producing a reference chamber filled with gas. In FIG. 6A, the first wafer 1 is provided and coated with the first bonding material 4 on its rear side. Preferably, the first bonding material 4 is gold and is applied to the rear side of the first wafer 1 via a sputtering process. In FIG. 6 B, the first bonding material 4 is structured on the rear side of the first wafer 1.

A top view of the structuring of the first bonding material 4 is illustrated on the right. In FIG. 6 C, a photoresist 8 is applied to the front side of the first wafer 1. In FIG. 6 D, starting from the front side, an opening 9 is formed in the first wafer 1 via an etching process, preferably via a dry etching process, particularly preferably via reactive ion deep etching. In FIG. 6 E, a second wafer 2 is bonded to the first wafer 1 at the contact areas 3. The second wafer comprises a second bonding material 5 at the contact surfaces 3, which is preferably gold, copper and/or aluminum. Preferably, the two wafers 1 and 2 are bonded together via TC—bonding. After the bonding process, in FIG. 6 F, a thermal solder 15 is applied near the opening 9. Then, in FIG. 6 G, the reference chamber within the coating system is flooded with the reference gas 11, e.g., ammonia. Finally, in FIG. 6 H, the thermal solder 15 is melted to flow into and seal the opening 9.

Furthermore, the reference chamber is coated with a cover layer 12, preferably a nitride, so that the reference chamber is particularly well hermetically sealed.

### LIST OF REFERENCE SIGNS

1 First wafer
2 Second wafer
3 Contact surface
4 First bonding material
5 Second bonding material
6 Cavity
7 Volume
8 Photoresist
9 Opening
11 Reference gas
12 Cover layer
13 Material layer for structuring as a valve
14 Valve
15 Solder

### BIBLIOGRAPHY

Bonilla-Manrique, Oscar E., et al. “Sub-ppm-Level Ammonia Detection Using Photoacoustic Spectroscopy with an Optical Microphone Based on a Phase Interferometer.” Sensors 19.13 (2019): 2890.
Peng, W. Y., et al. “High-sensitivity in situ QCLAS-based ammonia concentration sensor for high-temperature applications.” Applied Physics B 122.7 (2016): 188.
Schilt, Stéphane, et al. “Ammonia monitoring at trace level using photoacoustic spectroscopy in industrial and environmental applications. “Spectrochimica Acta Part A: Molecular and Biomolecular Spectroscopy 60.14 (2004): 3259-3268.
Stemme, Goran, and Edvard Kalvesten. “Micromachined gas-filled chambers and method of microfabrication.” U.S. Pat. No. 6,124,145. 26 Sep. 2000.

1. A method of producing a photoacoustic gas sensor comprising a gas-filled reference chamber within which a microelectromechanical system (MEMS) device and optionally an electronic circuit is present, comprising the steps of:
a) providing a first and second wafer, wherein at least the first wafer and/or the second wafer has a cavity and wherein the MEMS device is present on the first and/or second wafer, wherein the MEMS device is a MEMS sensor,
b) bonding the first wafer to the second wafer within a bonding chamber to form a volume which can be filled with reference gas, wherein an opening remains on a contact surface of the two wafers after bonding, or an opening is made in the first and/or second wafer before or after bonding,
c) flooding a reference gas into the reference chamber via the opening within a coating system,
d) sealing the opening of the reference chamber within the coating system
e) providing a modulable emitter,
f) arranging the reference chamber filled with the reference gas and the modulable emitter, wherein the reference chamber is present in the beam path of the emitter so that the emitter can excite the reference gas in the reference chamber by means of modulably emittable radiation to form sound pressure waves which are detectable by means of the MEMS sensor.

2. The production method according to claim 1, wherein the reference gas comprises corrosive and/or explosive gases.

3. The production method according to claim 1, wherein in order to set a partial pressure of the reference gas within the reference chamber, an inert gas is additionally introduced into the reference chamber via the opening.

4. The production method according to claim 1, wherein the first wafer and the second wafer have contact surfaces which are used for bonding the first wafer to the second wafer, wherein, in order to form the opening, a region on the contact surfaces is not bonded and/or wherein an opening remains on a contact surface of the two wafers after bonding, wherein the opening has a cross-section from 1 μm² to 1000 μm² and a length from 1 μm to 1000 μm.

5. The production method according to claim 1, wherein that before or after bonding the first wafer to the second wafer, the opening is formed starting from an outer side to an inner side of the first wafer or the second wafer.

6. The production method according to claim 1, wherein a valve is present at the end of the opening of the first or the second wafer, wherein after bonding of the first wafer with the second wafer the valve is located at the end of the opening starting from the outside of the first wafer or the second wafer and within the volume of the reference chamber.

7. The production method according to claim 1, wherein after bonding the first wafer to the second wafer, the reference chamber in the coating system is flooded with the reference gas, the gas entering the volume of the reference chamber via the opening and via the valve.

8. The production method according to claim 1, wherein after flooding the reference gas into the reference chamber for sealing the opening, a solder is melted.

9. The production method according to claim 1, wherein the opening is sealed by means of a coating process within the coating system.

10. The production method according to claim 1, wherein the coating system is a physical coating system or a chemical coating system, a low-pressure chemical coating system and/or epitaxial coating system.

11. The production method according to claim 1, wherein for sealing the opening-within the coating system, a covering layer is applied at least over a region of the opening, wherein a nitride, silicon carbonitride, silicon oxynitride, titanium nitride and/or tantalum nitride, an oxide, or a metal, is used as material for the covering layer.

12. The production method according to claim 1, wherein for sealing the opening and for forming a cover layer, a process gas is introduced in the coating system, wherein the process gas is introduced into the reference chamber after flooding with a reference gas, or wherein a material for forming the cover layer is selected in such a way that the reference gas can simultaneously serve as the process gas.

13. The production method according to claim 1, wherein the MEMS device comprises a MEMS sensor or a MEMS actuator and/or the electronic circuit comprises a processor, a switch, transistors, and/or transducers.

14. (canceled)

15. A photoacoustic gas sensor comprising:
a modulable emitter,
a reference chamber filled with a reference gas, wherein a MEMS sensor is present within the reference chamber,
wherein the reference chamber is present in the beam path of the emitter so that the emitter can excite the reference gas in the reference chamber by means of modulably emittable radiation to form sound pressure waves which are detectable by means of the MEMS sensor, characterized in that the photoacoustic gas sensor was produced by a method according to claim 1.

16. The photoacoustic gas sensor according to claim 15 wherein the reference chamber forms a sealed system which is filled with the reference gas and a gas to be analyzed is present in the beam path between the emitter and the reference chamber, so that the proportion of the reference gas in the gas to be analyzed can be measured by means of the formation of sound pressure waves in the reference chamber.

17. The production method according to claim 1, wherein the MEMS device is a sound pressure detector, wherein the sound pressure detector comprises a capacitively or optically readable, piezoelectric, piezoresistive and/or magnetic bar and/or a capacitive, piezoelectric, piezoresistive and/or optical microphone.

18. The production method according to claim 2, wherein the corrosive and/or explosive gasses comprise methane, propane, propylene, silane, chlorosilane, hydrogen, oxygen or ammonia.

19. The production method of claim 6, wherein the valve is a non-ferrous metal selected from the group comprising lead, gold, indium, copper, platinum, silver, zinc, tin, aluminum and a compound thereof.

20. The production method of claim 10, wherein the physical coating system is a plasma assisted physical coating system or wherein the chemical coating system is a plasma-assisted chemical coating system.

21. The production method of claim 11, wherein the covering layer is applied around the entire reference chamber.
